(19) United States
(12) Patent Application Publication
(10) Pub. No.: US 2024/0322091 A1
(43) Pub. Date: Sep. 26, 2024

(54) DISPLAY PANEL, DISPLAY DEVICE, AND PREPARATION METHOD THEREOF

(71) Applicant: Tianma Advanced Display Technology Institute (Xiamen) Co., Ltd., Xiamen (CN)

(72) Inventor: Sitao HUO, Xiamen (CN)

(73) Assignee: Tianma Advanced Display Technology Institute (Xiamen) Co., Ltd., Xiamen (CN)

(21) Appl. No.: 18/680,334

(22) Filed: May 31, 2024

(30) Foreign Application Priority Data
Jan. 19, 2024 (CN) 202410084934.1

(51) Int. Cl. H01L 33/56; H01L 25/075; H01L 33/00; H01L 33/58; H01L 33/62

(52) U.S. Cl. CPC H01L 33/56; H01L 25/0753; H01L 33/005; H01L 33/58; H01L 33/62

(57) ABSTRACT

A display panel includes a circuit substrate, multiple light-emitting components located on a side of the circuit substrate, and multiple microlenses. Each light-emitting component includes a first surface facing away from the circuit substrate and also includes a second surface at least partially surrounds the first surface. One of the first surface or the second surface is a hydrophilic surface, and the other is a hydrophobic surface. The multiple microlenses are located on a side of the multiple light-emitting components facing away from the circuit substrate. The orthographic projection of the microlens on the plane where the circuit substrate is located overlaps the orthographic projection of the first surface on the plane where the circuit substrate is located and does not overlap the orthographic projection of the second surface on the plane where the circuit substrate is located.

### CROSS-REFERENCE TO RELATED APPLICATION(S)

This application claims priority to Chinese Patent Application No. 202410084934.1 filed Jan. 19, 2024, the disclosure of which is incorporated herein by reference in its entirety.

### TECHNICAL FIELD

Embodiments of the present disclosure relate to the field of display technology, particularly a display panel, a display device, and a preparation method thereof.

### BACKGROUND

In recent years, with the development of high definition of a flat-panel display such as a mobile phone or a television, the requirement for a high performance of a light-emitting diode (LED) display has been increasingly higher, and the size of an LED element has gradually decreased. A micro-LED display that is more highly refined is gradually replacing a display such as a liquid crystal display, a plasma display, or an electroluminescent (EL) display.

However, a micro-LED has an inherent light pattern, so the light efficiency at the angle of front view is low, and the power consumption is high, affecting the display performance of the display panel.

### SUMMARY

In a first aspect, embodiments of the present disclosure provide a display panel. The display panel includes a circuit substrate, multiple light-emitting components, and multiple microlenses. The multiple light-emitting components are located on a side of the circuit substrate. At least one of the multiple light-emitting components includes a first surface facing away from the circuit substrate and also includes a second surface. The second surface at least partially surrounds the first surface. One of the first surface or the second surface is a hydrophilic surface. The other of the first surface or the second surface is a hydrophobic surface. The multiple microlenses are located on a side of the multiple light-emitting components facing away from the circuit substrate. The orthographic projection of a microlens of the multiple microlenses on the plane where the circuit substrate is located overlaps the orthographic projection of the first surface on the plane where the circuit substrate is located and does not overlap the orthographic projection of the second surface on the plane where the circuit substrate is located.

In a second aspect, embodiments of the present disclosure provide a display panel. The display panel includes a circuit substrate, multiple light-emitting components, and multiple microlenses. The multiple light-emitting components are located on a side of the circuit substrate. The light-emitting component includes a first surface facing away from the circuit substrate. The light-emitting component and/or the circuit substrate includes a second surface. The second surface at least partially surrounds the first surface. One of the first surface or the second surface is a hydrophilic surface. The other of the first surface or the second surface is a hydrophobic surface. The orthographic projection of a microlens of the multiple microlenses on the plane where the circuit substrate is located does not overlap the orthographic projection of the first surface on the plane where the circuit substrate is located and overlaps the orthographic projection of the second surface on the plane where the circuit substrate is located.

In a third aspect, embodiments of the present disclosure provide a display device. The display device includes a display panel. The display panel includes a circuit substrate, multiple light-emitting components, and multiple microlenses. The multiple light-emitting components are located on a side of the circuit substrate. At least one of the multiple light-emitting components includes a first surface facing away from the circuit substrate and also includes a second surface. The second surface at least partially surrounds the first surface. One of the first surface or the second surface is a hydrophilic surface. The other of the first surface or the second surface is a hydrophobic surface. The multiple microlenses are located on a side of the multiple light-emitting components facing away from the circuit substrate. The orthographic projection of the microlens on the plane where the circuit substrate is located overlaps the orthographic projection of the first surface on the plane where the circuit substrate is located and does not overlap the orthographic projection of the second surface on the plane where the circuit substrate is located.

In a fourth aspect, embodiments of the present disclosure provide a display device. The display device includes a display panel. The display panel includes a circuit substrate, multiple light-emitting components, and multiple microlenses. The multiple light-emitting components are located on a side of the circuit substrate. The light-emitting component includes a first surface facing away from the circuit substrate. The light-emitting component and/or the circuit substrate includes a second surface. The second surface at least partially surrounds the first surface. One of the first surface or the second surface is a hydrophilic surface. The other of the first surface or the second surface is a hydrophobic surface. The orthographic projection of a microlens of the multiple microlenses on the plane where the circuit substrate is located does not overlap the orthographic projection of the first surface on the plane where the circuit substrate is located and overlaps the orthographic projection of the second surface on the plane where the circuit substrate is located.

In a fifth aspect, embodiments of the present disclosure provide a preparation method of a display panel. The method is applied to prepare the display panel of the first aspect. The method includes preparing the circuit substrate; preparing the multiple light-emitting components on a side of the circuit substrate; and preparing the multiple microlenses. At least one of the multiple light-emitting components comprises the first surface facing away from the circuit substrate, and at least one of the multiple light-emitting components further comprises the second surface, the second surface at least partially surrounds the first surface, one of the first surface or the second surface is a hydrophilic surface, and the other of the first surface or the second surface is a hydrophobic surface. The multiple microlens are located on the side of the multiple light-emitting components facing away from the circuit substrate, and an orthographic projection of a microlens of the multiple microlens on the plane where the circuit substrate is located overlaps an orthographic projection of the first surface on the plane where the circuit substrate is located and does not overlap an orthographic projection of the second surface on the plane where the circuit substrate is located.

### BRIEF DESCRIPTION OF DRAWINGS

FIG. 1 is a section view of a micro-LED display panel according to the related art.

FIG. 2 is a far-field radiation pattern of red, green, and blue micro-LEDs obtained by simulation and experiment according to the related art.

FIG. 3 is a diagram illustrating the structure of a display panel according to an embodiment of the present disclosure.

FIG. 4 is a section view taken along AA′ of the display panel shown in FIG. 3.

FIG. 5 is another section view of a display panel according to an embodiment of the present disclosure.

FIG. 6 is another section view of a display panel according to an embodiment of the present disclosure.

FIG. 7 is another section view of a display panel according to an embodiment of the present disclosure.

FIG. 8 is another section view of a display panel according to an embodiment of the present disclosure.

FIG. 9 is another section view of a display panel according to an embodiment of the present disclosure.

FIG. 10 is another section view of a display panel according to an embodiment of the present disclosure.

FIG. 11 is another section view of a display panel according to an embodiment of the present disclosure.

FIG. 12 is another section view of a display panel according to an embodiment of the present disclosure.

FIG. 13 is another section view of a display panel according to an embodiment of the present disclosure.

FIG. 14 is another section view of a display panel according to an embodiment of the present disclosure.

FIG. 15 is another diagram illustrating partial structure of a display panel according to an embodiment of the present disclosure.

FIG. 16 is a section view taken along BB′ of the display panel shown in FIG. 15.

FIG. 17 is a section view taken along CC′ of the display panel shown in FIG. 15.

FIG. 18 is another section view of a display panel according to an embodiment of the present disclosure.

FIG. 19 is another section view of a display panel according to an embodiment of the present disclosure.

FIG. 20 is another diagram illustrating the structure of a display panel according to an embodiment of the present disclosure.

FIG. 21 is a section view taken along DD′ of the display panel shown in FIG. 20.

FIG. 22 is another section view taken along DD′ of the display panel shown in FIG. 20.

FIG. 23 is another diagram illustrating the structure of a display panel according to an embodiment of the present disclosure.

FIG. 24 is a section view taken along EE′ of the display panel shown in FIG. 23.

FIG. 25 is another section view taken along EE′ of the display panel shown in FIG. 23.

FIG. 26 is a flowchart of a preparation method of a display panel according to an embodiment of the present disclosure.

FIG. 27 is another diagram illustrating the structure of a display panel according to an embodiment of the present disclosure.

FIG. 28 is a section view taken along FF′ of the display panel shown in FIG. 27.

FIG. 29 is another section view of a display panel according to an embodiment of the present disclosure.

FIG. 30 is another section view of a display panel according to an embodiment of the present disclosure.

FIG. 31 is another section view of a display panel according to an embodiment of the present disclosure.

FIG. 32 is another diagram illustrating partial structure of a display panel according to an embodiment of the present disclosure.

FIG. 33 is a section view taken along GG′ of the display panel shown in FIG. 32.

FIG. 34 is another section view of a display panel according to an embodiment of the present disclosure.

FIG. 35 is another section view of a display panel according to an embodiment of the present disclosure.

FIG. 36 is another diagram illustrating the structure of a display panel according to an embodiment of the present disclosure.

FIG. 37 is a section view taken along HH′ of the display panel shown in FIG. 36.

FIG. 38 is another section view taken along HH′ of the display panel shown in FIG. 36.

FIG. 39 is another section view of a display panel according to an embodiment of the present disclosure.

FIG. 40 is a flowchart of another preparation method of a display panel according to an embodiment of the present disclosure.

FIG. 41 is a diagram illustrating the structure of a display device according to an embodiment of the present disclosure.

### REFERENCE LIST

AA—display region, BA—bonding region, S1—first surface, S2—second surface
1—circuit substrate, 10—pixel circuit, 101—supporting substrate, 102—circuit film, 11—gate driving circuit, 12—scan signal line, 13—data signal line, 100—display panel
2—light-emitting component, 20—light-emitting element, 20′—micro light-emitting diode, 21—first modified film, 2101—top surface, 2102—lateral surface, 211—first portion, 212—second portion, 22—second modified film, 223—third portion, 224—fourth portion, 201—first light-emitting component, 202—second light-emitting component, 2001—first-color light-emitting component, 2002—second-color light-emitting component, 2003—third-color light-emitting component
3—microlens, 301—first microlens, 302—second microlens, 31—upper portion, 32—lower portion, 4—planarization layer, 5—fill layer

### DETAILED DESCRIPTION

Terms used in the embodiments of the present disclosure are intended only to describe the specific embodiments and not to limit the present disclosure. It is to be noted that nouns of locality such as “on”, “below”, “left”, and “right” in the embodiments of the present disclosure are described from angles shown in the figures and are not to be construed as limiting the embodiments of the present disclosure. Additionally, in the context, it is to be understood that when an element is formed “on” or “below” another element, the element can not only be directly formed “on” or “below” the other element but also be indirectly formed “on” or “below” the other element via an intermediate element. Terms such as “first” and “second” are used only for the purpose of description to distinguish between different components and not to indicate any order, quantity, or importance. For those of ordinary skill in the art, specific meanings of the preceding terms in the present disclosure may be understood based on specific situations.

The terms “comprise”, “include”, and variations thereof in the present disclosure are intended to be inclusive, that is, “including, but not limited to”. The term “based on” is “at least partially based on”. The term “an embodiment” refers to “at least one embodiment”.

It is to be noted that references to “first”, “second”, and the like in the present disclosure are merely intended to distinguish corresponding content and are not intended to limit an order or an interrelationship.

It is to be noted that “one” and “multiple” mentioned in the present disclosure are illustrative and not limiting, and that those skilled in the art should understand that “one” and “multiple” should be construed as “one or more” unless clearly indicated in the context.

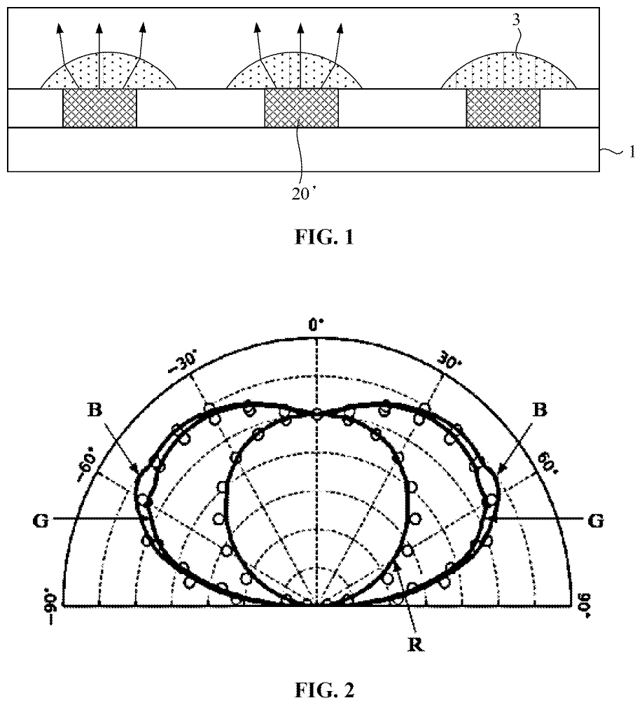

FIG. 1 is a section view of a micro-LED display panel according to the related art. Referring to FIG. 1, as described in the background, in an existing micro-LED display panel, micro light-emitting diodes 20′ of different colors are bonded on a circuit substrate 1 to form a pixel unit, thereby implementing the display function of the panel. FIG. 2 is a far-field radiation pattern of red, green, and blue micro-LEDs obtained by simulation and experiment according to the related art. In FIG. 2, a curve represents a simulation result, and a point represents an experiment result. Referring to FIG. 2, micro light-emitting diodes of different colors have different light intensity distribution patterns at different angles of view, that is, have their respective inherent light patterns. Moreover, as can be seen from the light pattern, red, green, and blue micro light-emitting diodes, especially green and blue micro light-emitting diodes, emit more light at an angle of oblique view (non-0° angle of view) and have a worse light effect at the front angle of view (0° angle of view), resulting in a relatively high power consumption of the micro light-emitting diodes.

Continuing to refer to FIG. 1, currently, to optimize the exit light path of the micro light-emitting diodes and improve the light exit efficiency, a microlens layer is disposed on the light exit side of the micro light-emitting diodes to form a microlens panel. Microlenses 3 are disposed in the microlens layer. The microlenses 3 are in one-to-one correspondence with the micro light-emitting diodes 20′, thus implementing the focusing effect of the exit light of the micro light-emitting diodes 20′. However, the microlenses 3 require to be precisely aligned with the respective micro light-emitting diodes 20′. Therefore, insufficient alignment precision may cause a large alignment error between different microlenses 3 and the respective micro light-emitting diodes 20′ and thus cause a large difference among the light exit paths of different microlenses 3, causing the problem of nonuniform display of the display panel.

In view of this problem, embodiments of the present disclosure provide a display panel as described in the following, and a preparation method thereof.

The display panel includes a circuit substrate, multiple light-emitting components, and multiple microlenses. The multiple light-emitting components are located on a side of the circuit substrate. Each light-emitting component includes a first surface facing away from the circuit substrate and also includes a second surface. The second surface at least partially surrounds the first surface. One of the first surface or the second surface is a hydrophilic surface. The other of the first surface or the second surface is a hydrophobic surface. The multiple microlenses are located on a side of the multiple light-emitting components facing away from the circuit substrate. The orthographic projection of the microlens on the plane where the circuit substrate is located overlaps the orthographic projection of the first surface on the plane where the circuit substrate is located and does not overlap the orthographic projection of the second surface on the plane where the circuit substrate is located.

First, in one or more embodiments of the present disclosure, in the process of preparing the display panel, the microlens is formed on the light-emitting component. The display panel is prepared such that the light-emitting component has the first surface and the second surface, one of the first surface or the second surface is a hydrophilic surface, and the other of the first surface or the second surface is a hydrophobic surface; such that the microlens has a stronger affinity with the first surface and has a repellency against the second surface after hydrophilicity or hydrophobicity of the first surface or the second surface is used and the material of the microlens is selected properly; and such that the material of the microlens resides on the first surface and limited by the second surface to make the projection of the finally formed microlens overlap the projection of the first surface and not overlap the projection of the second surface. Thus, the first surface and the second surface that are different in hydrophilicity or hydrophobicity on the light-emitting elements enable position limitation and automatic alignment of the microlens when the microlens are prepared on the respective light-emitting elements, saving the trouble of aligning the microlens with the light exit sides of the light-emitting elements by the outside and preventing the problem of nonuniform display caused by an excessive difference between the positions of the light-emitting elements relative to the respective microlenses due to insufficient external alignment precision.

The preceding is the core idea of the display panel and the preparation method thereof according to the present disclosure. Solutions of the display panel and the preparation method thereof according to the present disclosure are described clearly and completely hereinafter in conjunction with drawings in embodiments of the present disclosure. Based on embodiments of the present disclosure, all other embodiments obtained by those of ordinary skill in the art without any creative effort are within the scope of the present disclosure.

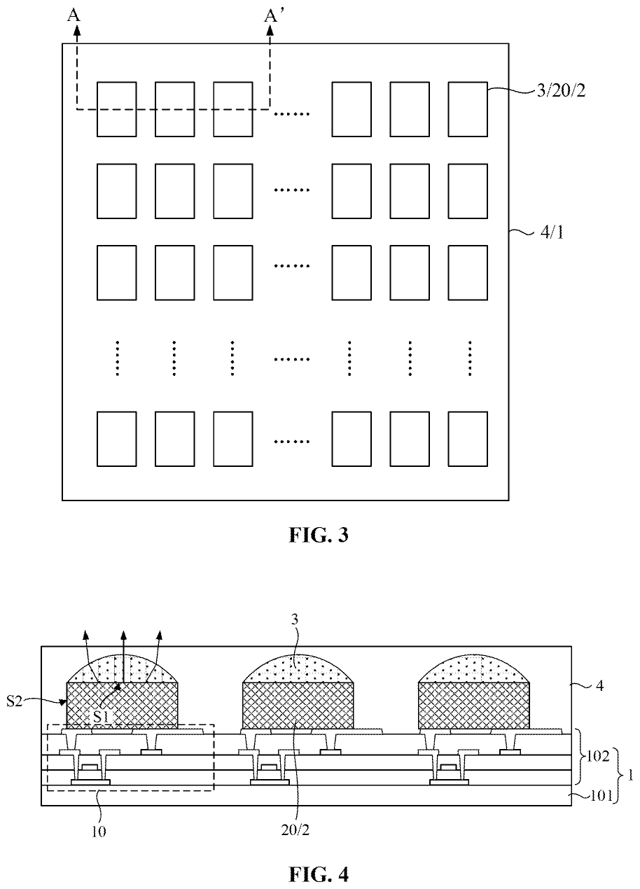

FIG. 3 is a diagram illustrating the structure of a display panel according to an embodiment of the present disclosure. FIG. 4 is a section view taken along AA′ of the display panel shown in FIG. 3. Referring to FIGS. 3 and 4, the display panel includes a circuit substrate 1, multiple light-emitting components 2, and multiple microlenses 3. The light-emitting components 2 are located on a side of the circuit substrate 1. At least one of the light-emitting components 2 facing away from the circuit substrate 1 includes a first surface S1 and also includes a second surface S2. The second surface S2 at least partially surrounds the first surface S1. One of the first surface S1 or the second surface S2 is a hydrophilic surface. The other of the first surface S1 or the second surface S2 is a hydrophobic surface. The multiple microlenses 3 are located on a side of the multiple light-emitting components 2 facing away from the circuit substrate 1. The orthographic projection of the microlens 3 on the plane where the circuit substrate 1 is located overlaps the orthographic projection of the first surface S1 on the plane where the circuit substrate 1 is located and does not overlap the orthographic projection of the second surface S2 on the plane where the circuit substrate is located.

The light-emitting component 2 includes a light-emitting element 20. The light-emitting element 20 is responsible for emitting light of a certain color. Light-emitting elements 20 of different colors may be combined to form a pixel unit. The light-emitting elements 20 are electrically connected to the circuit substrate 1. A pixel circuit 10 is disposed on the circuit substrate 1 to control light emission and brightness of the light-emitting elements 20. Light-emitting elements 20 of different colors in a pixel unit cooperate in terms of luminance and brightness to achieve a color matching effect to make the pixel unit to emit a certain color. Image display of the display panel can be implemented by cooperation between pixel units macroscopically.

The light-emitting element 20 in the light-emitting component 2 may be, but is not limited to, a light-emitting diode (LED), a micro light-emitting diode (micro-LED), a mini light-emitting diode (mini-LED), or a nano light-emitting diode (nano-LED). The light-emitting component 2 is formed by processing of the light-emitting element 20. The difference between the light-emitting component 2 and the light-emitting element 20 is that the light-emitting component 2 has the first surface S1 and the second surface S2, where one of the first surface S1 or the second surface S2 is a hydrophilic surface, and the other of the first surface S1 or the second surface S2 is a hydrophobic surface. In other words, the light-emitting component 2 of this embodiment of the present disclosure is the light-emitting element 20 added with the first surface S1 and the second surface S2 that are different in hydrophilicity or hydrophobicity. It is to be understood that there is a certain position relationship between the second surface S2 and the first surface S1 on the light-emitting component 2, that is, the second surface S2 at least partially surrounds the first surface S1. The second surface S2 and the first surface S1 may be in the same plane or may be not in the same plane, as shown in FIGS. 3 and 4. It is to be understood that in terms of the light-emitting component 2 as a three-dimensional structure, the surface of the light-emitting component 2 where the electrode is located requires to face the circuit substrate 1 to be electrically connected to the driver circuit on the circuit substrate 1, and other surfaces of the light-emitting component 2 are naked relative to the circuit substrate 1. The second surface S2 surrounding the first surface S1 is based on the naked surface of the light-emitting component 2. When the naked surface of the light-emitting component 2 is unfolded to be in a same plane, the second surface S2 at least partially surrounds the first surface S1.

As described earlier, the first surface S1 and the second surface S2 serve to enable automatic alignment between the microlens 3 and the light-emitting element 20 in the preparation process. One of the first surface S1 or the second surface S2 is a hydrophilic surface, the other of the first surface S1 or the second surface S2 is a hydrophobic surface, and the second surface S2 at least partially surrounds the first surface S1, so when a suitable material is used to preparation of the microlens 3, the affinity of the material with the first surface S1 and the repellency of the microlens 3 against the second surface S2 make the microlens 3 attached to the first surface S1. Due to that the second surface S2 surrounds the first surface S1 and repels the microlens 3, the microlens 3 automatically moves to the area where the first surface S1 is located. The projection of the microlens 3 on the circuit substrate 1 overlaps the projection of the first surface S1 on the circuit substrate 1 and does not overlap the projection of the second surface S2 on the circuit substrate 1, enabling the automatic alignment function of the microlens 3. The circuit substrate 1 is configured to carry and drive the light-emitting elements 20 and is formed by a supporting substrate 101 and a circuit film 102 on the supporting substrate 101. Considering that the supporting substrate 101 is flat while the circuit film 102 may have dents or bumps on the surface of the circuit film 102, the orthographic projection of the plane where the circuit substrate 1 is located may be construed as the orthographic projection of the plane where the supporting substrate 101 is located. Moreover, the microlens 3 formed on the first surface S1 may be construed as a planoconvex lens. The shape of the bottom surface of the microlens 3 depends on the shape of the first surface S1. As shown in the figures, the orthographic projection of the example light-emitting component 2 on the plane where the circuit substrate 1 is located is rectangular, and the first surface S1 is also rectangular. Therefore, the bottom surface of the microlens 3 and the orthographic projection of the microlens 3 on the plane where the circuit substrate 1 is located are also rectangular.

Therefore, the position of the microlens 3 depends on the position of the first surface S1 and the position of the second surface S2. In the light-emitting component 2 of this embodiment, the first surface S1 is disposed on the surface of the light-emitting component 2 facing away from the circuit substrate 1, that is, the microlens 3 can automatically move to the surface of the light-emitting component 2 facing away from the circuit substrate 1. Thus, the microlens 3 can focus light emitted from the surface of the light-emitting component 2 facing away from the circuit substrate 1, improving the pattern of the exit light of the light-emitting element 20, making more light emitted from the light-emitting element 20 at the angle of front view, increasing the effect of light emitted from the light-emitting element 20 at the angle of front view, and thereby improving the display effect.

Further, the orthographic projection of the microlens 3 on the plane where the circuit substrate 1 is located coincides with the orthographic projection of the first surface 1 on the plane where the circuit substrate 1 is located.

Projection coincidence between the microlens 3 and the first surface S1 means that the microlens 3 can completely cover the first surface S1 so that the first surface S1 of the light-emitting component 2 can be fully used so that a largest possible microlens 3 can be formed so that the microlens 3 can cover a largest possible area on the surface of the light-emitting component 2 facing away from the circuit substrate 1 side and thus can fully focus light emitted from the light-emitting component 2.

In the embodiments of the present disclosure, the first surface S1 may be a hydrophilic surface, and the second surface S2 may be a hydrophobic surface. The hydrophilic surface and the hydrophobic surface may be construed as absolute concepts. The droplet contact angle on the surface represents hydrophilicity or hydrophobicity of the first surface or the second surface. The droplet contact angle on the hydrophilic surface should be less than 90°. The droplet contact angle on the hydrophobic surface should be greater than 90°. Based on this, further, the droplet contact angle on the hydrophilic surface may be set less than 75°, and the droplet contact angle on the hydrophobic surface may be set greater than 100°. In this case, the microlens 3 may be made of a hydrophilic polymer. The microlens 3 made of a hydrophilic polymer has an affinity with the first surface S1 as a hydrophilic surface and has a repellency against the second surface S2 as a hydrophobic surface. Thus, the microlens 3 can automatically move to the first surface S1. In one or more embodiments, the first surface S1 may be a hydrophobic surface, and the second surface S2 may be a hydrophilic surface. In this case, the microlens 3 may be made of a hydrophobic polymer. The microlens 3 made of a hydrophobic polymer has an affinity with the first surface S1 as a hydrophobic surface and has a repellency against the second surface S2 as a hydrophilic surface. Thus, the microlens 3 can automatically move to the first surface S1. The hydrophilic polymer of this embodiment of the present disclosure may be a polyethylene oxide, polylactic acid, poly-4-vinylpyridine, polyvinyl ester, polyvinyl ether, polyvinyl ketone, polyvinylpyridine, polyvinylpyrrolidone, polybutadiene, polypropylene, or polyethylene-propylene-diene polymer. The hydrophobic polymer may be a polyvinyl chloride, polyethylene, polypropylene, polymethyl methacrylate, polyethyl methacrylate, polyprene, polyamide-6, polycarbonate, polyethylene terephthalate, or polystyrene polymer. The hydrophilic polymer and the hydrophobic polymer herein are examples. Other hydrophilic or hydrophobic materials may be selected according to the actual requirements.

In one or more embodiments, the hydrophilic surface and the hydrophobic surface may be construed as relative concepts. The droplet contact angle on the surface represents hydrophilicity or hydrophobicity of the first surface or the second surface. The droplet contact angle on the hydrophilic surface should be less than the droplet contact angle on the hydrophobic surface. Based on the difference between droplet contact angles, the first surface S1 as a hydrophilic surface has a higher affinity that makes the microlens 3 attached to the first surface S1 and thus enables automatic alignment of the microlens 3.

Referring to FIG. 4, in one or more embodiments of the present disclosure, the display panel also includes a planarization layer 4. The planarization layer 4 is located on the side of the microlens 3 facing away from the circuit substrate 1. The refractive index of the planarization layer 4 is less than the refractive index of the microlens 3.

It is to be understood that focusing of light by the microlens 3 depends on the refractive index of the microlens 3 and the external refractive index as well as the shape of the microlens 3. As shown in FIG. 4, in the display panel of this embodiment, the planarization layer 4 is located on the side of the microlens 3 facing away from the circuit substrate 1. The planarization layer 4 covers and surrounds the microlens 3 so that light emitted from the surface of the light-emitting component 2 facing away from the circuit substrate 1 requires to pass through the microlens 3 and the planarization layer 4 in sequence before being output. The refractive index of the planarization layer 4 is less than the refractive index of the microlens 3, and the microlens 3 formed on the surface of the light-emitting component 2 is a flat convex lens; therefore, light incident on the inside of the microlens 3 is in a light-tight to light-sparse propagation process when entering the planarization layer 4. Light is refracted on the contact position between the microlens 3 and the planarization layer 4 and is deflected toward the central optical axis of the microlens 3, thereby implementing the focusing effect of the light.

This embodiment of the present disclosure provides different implementations of forming the first surface S1 and the second surface S2 on the light-emitting component. FIG. 5 is another section view of a display panel according to an embodiment of the present disclosure. Referring to FIG. 5, in one or more embodiments, the light-emitting component 2 includes a light-emitting element 20, a first modified film 21, and a second modified film 22. One of the first modified film 21 or the second modified film 22 is made of a hydrophilic material. The other of the first modified film 21 or the second modified film 22 is made of a hydrophobic material.

The surface of the light-emitting element 20 facing away from the circuit substrate 1 is a top surface 2101. The surface of the light-emitting element 20 adjacent to the top surface 2101 is a lateral surface 2102. The first modified film 21 is at least partially located on the top surface 2101. The second modified film 22 is located on the top surface 2101 and/or the lateral surface 2102.

The first surface S1 is the surface of the first modified film 21 facing away from the light-emitting element 20. The second surface S2 is the surface of the second modified film 22 facing away from the light-emitting element 20.

The first modified film 21 and the second modified film 22 are films additionally formed on the light-emitting element 20 and configured to perform hydrophilic or hydrophobic modification on the surface of the light-emitting element 20. The light-emitting element 20 plus the first modified film 21 and the second modified film 22 on the light-emitting element 20 constitute the light-emitting component 2. The first modified film 21 is configured to cause a part of the surface of the light-emitting element 20 to constitute the first surface S1, and the second modified film 22 is configured to cause a part of the surface of the light-emitting element 20 to constitute the second surface S2. The first modified film 21 corresponds to the first surface S1, and the second modified film 22 corresponds to the second surface S2. One of the first modified film 21 or the second modified film 22 is a hydrophilic film, and the other of the first modified film 21 or the second modified film 22 is a hydrophobic film. For example, the first surface S1 is a hydrophilic surface, the first modified film 21 is a hydrophilic film, the second surface S2 is a hydrophobic surface, and the second modified film 22 is a hydrophobic film. In this case, the first modified film 21 may be made of a hydrophilic polymer, and the second modified film 22 may be made of a hydrophobic film. The hydrophilic polymer and the hydrophobic polymer are as described earlier, which are not repeated herein. In one or more embodiments, the first modified film 21 may be made of a hydrophobic polymer to constitute a hydrophobic film, and the second modified film 22 may be made of a hydrophilic polymer to constitute a hydrophilic film.

In terms of the light-emitting element 20 electrically connected to the circuit substrate 1, the surface on which the electrode is disposed may be construed as the bottom surface of the light-emitting element 20, and the surface facing away from the circuit substrate 1 may be construed as the top surface of the light-emitting element 20. The bottom surface of the light-emitting element 20 is bonded to the circuit substrate 1. The top surface of the light-emitting element 20 is used for emitting light outwards. The light-emitting element 20 also has a lateral surface 2102 connecting the bottom surface and the top surface 2101. Relative to the circuit substrate 1, the top surface 2101 and the lateral surface 2102 are each a naked surface. This embodiment is essentially a solution of hydrophilic or hydrophobic modification of the naked top surface 2101 and the naked lateral surface 2102 of the light-emitting element 20, that is, a solution of forming the first modified film 21 and the second modified film 22 in some areas of the top surface 2101 and the lateral surface 2102 of the light-emitting element 20. Specifically, based on that the first modified film 21 and the second modified film 22 are used for forming the first surface S1 and the second surface S2 respectively, the first modified film 21 is at least partially located on the top surface 2101, and the second modified film 22 is located on the top surface 2101 or the lateral surface 2102 of the light-emitting element 20 to surround the first modified film 21. Therefore, in the preparation process of the microlens 3, the surface of the first modified film 21 facing away from the light-emitting element 20, that is, the first surface S1, can have an affinity with the material of the microlens 3, and the surface of the second modified film 22 facing away from the light-emitting element 20, that is, the second surface S2, can have a repellency against the material of the microlens 3, so that the material of the microlens 3 is limited in the area where the first surface S1 is located, and the microlens 3 is automatically aligned and formed on the top surface 2101 of the light-emitting element 20.

In practice, considering that the position and shape of the microlens both depend on the first surface and the second surface, the position of the first modified film and the position of the second modified film on the light-emitting element may be configured according to the actual requirements of the microlens. In view of this, the present disclosure illustrates various embodiments hereinafter.

Continuing to refer to FIG. 5, in one or more embodiments, the first modified film 21 is located on the top surface 2101, and the orthographic projection of the first modified film 21 on the plane where the circuit substrate 1 is located coincides with the orthographic projection of the top surface 2101 on the plane where the circuit substrate 1 is located.

In the embodiments, the first modified film 21 is not only located on the top surface 2101 of the light-emitting element 20, but also coincides with the orthographic projection of the top surface 2101 on the plane where the circuit substrate 1 is located, that is, the first modified film 21 completely covers the top surface 2101 of the light-emitting element 20. Thus, the surface of the first modified film 21 facing away from the light-emitting element 20, that is, the first surface S1, actually also coincides with the projection of the top surface 2101 of the light-emitting element 20. The first modified film 21 actually implements modification processing on the top surface 2101 of the light-emitting element 20. In this case, because the first surface S1 having hydrophilicity or hydrophobicity replaces the top surface 2101 of the light-emitting element 20, in the preparation process of the microlens 3, the material of the microlens 3 can be attached to the first surface S1 to completely cover the top surface 2101 of the light-emitting element 20 to fully focus all light emitted from the top surface 2101 of the light-emitting element 20, thereby avoiding light leakage, improving the light energy utilization of the light-emitting element 20, and reducing the energy consumption of the light-emitting element 20.

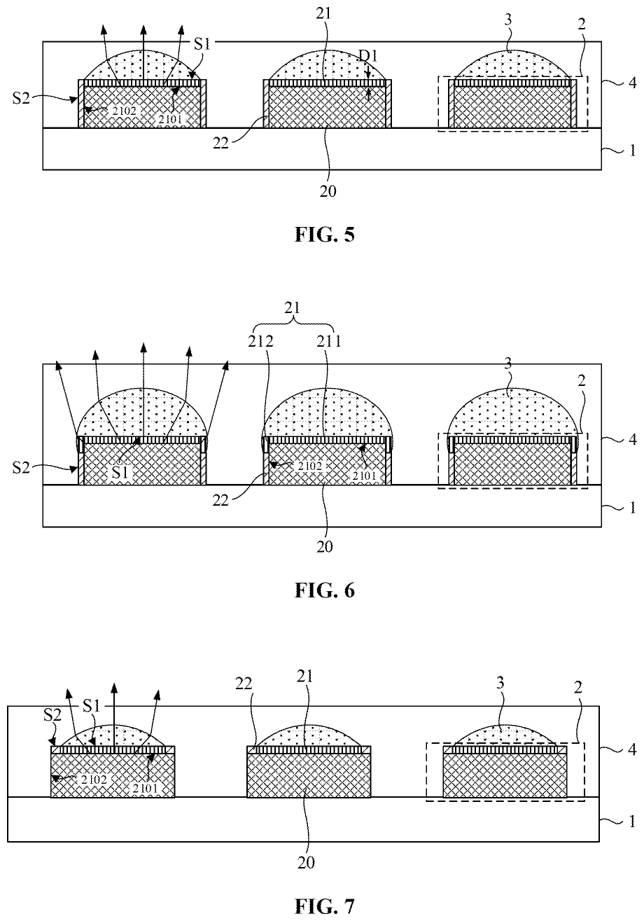

FIG. 6 is another section view of a display panel according to an embodiment of the present disclosure. Referring to FIG. 6, in the embodiments, the first modified film 21 includes a first portion 211 and a second portion 212 that are integrally connected. The first portion 211 is located on the top surface 2101. The second portion 212 is located on the lateral surface 2102. The orthographic projection of the first portion 211 on the plane where the circuit substrate 1 is located coincides with the orthographic projection of the top surface 2101 on the plane where the circuit substrate 1 is located. The orthographic projection of the second portion 212 on the plane where the circuit substrate 1 is located does not overlap the orthographic projection of the top surface 2101 on the plane where the circuit substrate 1 is located.

In the embodiments, the first modified film 21 includes a first portion 211 and a second portion 212 that are integrally connected. The first portion 211 is located on the top surface 2101 of the light-emitting element 20. The second portion 212 is located on the lateral surface 2102 of the light-emitting element 20. That is, the first modified film 21 not only covers the top surface 2101 of the light-emitting element 20, but also extends to an area of the lateral surface 2102 of the light-emitting element 20 adjacent to the top surface 2101. In this case, the surface of the first modified film 21 facing away from the light-emitting element 20, that is, the first surface S1, is not only located on the top surface 2101 of the light-emitting element 20, but also extends to an area of the lateral surface 2102 adjacent to the top surface 2101. When the microlens 3 is prepared, the material of the microlens 3 is attached to the first surface S1 so that the finally formed microlens 3 covers the top surface 2101 of the light-emitting element 20 and the area of the lateral surface 2102 adjacent to the top surface 2101. That is, the microlens 3 wraps the top of the light-emitting element 20. The microlens 3 can not only fully focus all light emitted from the top surface 2101 of the light-emitting element 20, thereby avoiding light leakage, improving the light energy utilization of the light-emitting element 20, and reducing the energy consumption of the light-emitting element 20; but can also use and focus light emitted from the upper area of the lateral surface 2102 of the light-emitting element 20, thereby better improving the light energy utilization of the light-emitting element 20 and reducing the energy consumption of the light-emitting element 20.

For the position design of the second modified film, continue referring to FIGS. 5 and 6. In one or more embodiments, the second modified film 22 is located on the lateral surface 2102, and the orthographic projection of the second modified film 22 on the plane where the circuit substrate 1 is located does not overlap the orthographic projection of the top surface 2101 on the plane where the circuit substrate 1 is located.

In the embodiments, the second modified film 22 is located on the lateral surface 2102, and among the naked surfaces of the light-emitting element 20, the second modified film 22 surrounds the first modified film 21 located on the top surface 2101 or on the top surface 2101 and part of the lateral surface 2102. In this case, when the microlens 3 is prepared, the material of the microlens 3 repels the surface of the second modified film 22, that is, the second surface S2, and has an affinity with the first modified film 21, so the microlens 3 can be automatically limited on the surface of the first modified film 21, that is, the first surface S1.

FIG. 7 is another section view of a display panel according to an embodiment of the present disclosure. Referring to FIG. 7, in one or more embodiments, the second modified film 22 is located on the top surface 2101, and the orthographic projection of the second modified film 22 on the plane where the circuit substrate 1 is located surrounds the orthographic projection of the first modified film 21 on the plane where the circuit substrate 1 is located.

In the embodiments, the second modified film 22 and the first modified film 21 are both located on the top surface 2101 of the light-emitting element 20. The second modified film 22 is formed on the edge area of the top surface 2101 of the light-emitting element 20, and the first modified film 21 is formed on the middle area of the top surface 2101 of the light-emitting element 20; thus, the second modified film 22 on the top surface 2101 surrounds the first modified film 21 on the top surface 2101. In the preparation of the microlens 3, the microlens 3 can be limited by the second modified film 22 onto the surface of the first modified film 21, that is, the first surface S1, to implement automatic alignment of the microlens 3.

Moreover, in the embodiments, the area where the microlens 3 is located depends on the first surface S1, that is, the first modified film 21, and also depends on the area formed by the second surface S2, that is, the second modified film 22. Therefore, for light-emitting elements 20 of different types and at different positions, the area of the second modified film 22 on the top surface 2101 of the light-emitting element 20 may be adaptively set so that microlenses 3 corresponding to different light-emitting elements 20 are differentiated, thereby compensating for and overcoming light exit differences caused by different types and positions of different light-emitting elements 20 and thus preventing the problem of nonuniform display.

FIG. 8 is another section view of a display panel according to an embodiment of the present disclosure. Referring to FIG. 8, in one or more embodiments, the second modified film 22 may include a third portion 223 and a fourth portion 224 that are integrally connected. The third portion 223 is located on the top surface 2101. The fourth portion 224 is located on the lateral surface 2102. The orthographic projection of the third portion 223 on the plane where the circuit substrate 1 is located coincides with the orthographic projection of the top surface 2101 on the plane where the circuit substrate 1 is located. The orthographic projection of the fourth portion 224 on the plane where the circuit substrate 1 is located does not overlap the orthographic projection of the top surface 2101 on the plane where the circuit substrate 1 is located.

In the embodiments, the second modified film 22 includes a third portion 223 and a fourth portion 224 that are integrally connected. The third portion 223 is located on the top surface 2101 of the light-emitting element 20. The fourth portion 224 is located on the lateral surface 2102 of the light-emitting element 20. That is, the second modified film 22 not only covers the lateral surface 2102 of the light-emitting element 20, but also extends to an edge area of the top surface 2101 of the light-emitting element 20. In this case, what actually acts in the second modified film 22 is the fourth portion 224. The fourth portion 224 and the first modified film 21 are both located on the top surface 2101 of the light-emitting element 20. The fourth portion 224 surrounds the first modified film 21. When the microlens 3 is prepared, the surface of the fourth portion 224 serves as the second surface S2 to limit the material of the microlens 3 onto the surface of the first modified film 21, that is, the first surface S1, so that the microlens 3 can implement the automatic alignment function.

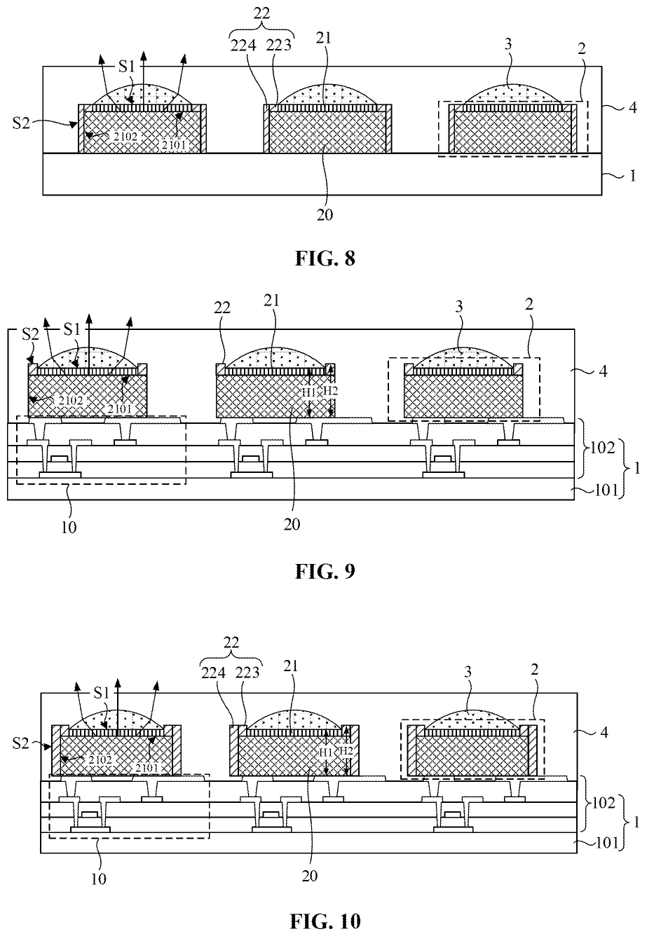

FIG. 9 is another section view of a display panel according to an embodiment of the present disclosure. FIG. 10 is another section view of a display panel according to an embodiment of the present disclosure. Referring to FIGS. 9 and 10, in one or more embodiments, in the direction perpendicular to the plane where the circuit substrate 1 is located, the distance between the surface of the first modified film 21 facing away from the circuit substrate 1 and the surface of the circuit substrate 1 is H1, and the distance between the surface of the second modified film 22 facing away from the circuit substrate 1 and the surface of the circuit substrate 1 is H2. H2>H1.

First, as mentioned earlier, the circuit substrate 1 of the present disclosure is actually composed of a supporting substrate 101 and a circuit film 102 located on the supporting substrate. Considering that there may be dents and bumps on the surface of the circuit film 102, the direction perpendicular to the plane where the circuit substrate 1 is located may be construed as the direction perpendicular to the plane where the supporting substrate 101 is located. This embodiment is essentially a solution of differentiating the distance between the surface of the first modified film 21 facing away from the circuit substrate 1, that is, the upper surface of the first modified film 21, and the surface of the circuit substrate 1 from the distance between the surface of the second modified film 22 facing away from the circuit substrate 1, that is, the upper surface of the second modified film 22, and the surface of the circuit substrate 1. Specifically, the distance H2 between the upper surface of the second modified film 22 and the surface of the circuit substrate 1 is greater than the distance H1 between the upper surface of the first modified film 21 and the surface of the circuit substrate 1. Here, the surface of the circuit substrate 1 is construed as a flat surface, that is, the same comparison reference is used. Therefore, that H2 is greater than H1 means that the second modified film 22 is thicker than the first modified film 21. Thus, there is a step difference at the contact position between the second modified film 22 and the first modified film 21. When the microlens 3 is prepared, on the one hand, an affinity of the first modified layer 21 and a repellency of the second modified layer 22 make the material of the microlens 3 attached to the first surface S1; on the other hand, the higher second modified layer 22 surrounds the lower first modified layer 21, forming a recess, and the wall of the recess (i.e., the step difference) imposes a horizontal resistance on the material of the microlens 3, limiting the microlens 3 into the recess. By using the preceding two action principles, the microlens 3 can automatically and effectively retain on the first surface S1 during preparation, thereby improving the success rate of automatic alignment of the microlens 3 and better improving the automatic alignment function of the microlens 3. It is to be added that, as described earlier, the circuit substrate 1 includes a supporting substrate 101 and a circuit film 102 on the supporting substrate 101, so the surface of the circuit film 102 may have dents and bumps. To avoid different comparison references for distances to the surface of the circuit substrate 1, that the distance H2 between the upper surface of the second modified film 22 and the surface of the circuit substrate 1 is greater than the distance H1 between the upper surface of the first modified film 21 and the surface of the circuit substrate 1 may be equivalent to that the distance H2 between the upper surface of the second modified film 22 and the surface of the supporting substrate 101 is greater than the distance H1 between the upper surface of the first modified film 21 and the surface of the supporting substrate 101. Since the supporting substrate 101 is usually flat, that the distance between the second modified film 22 and the supporting substrate 101 is different from the distance between the first modified film 21 and the supporting substrate 101 means that there is a height difference between the upper surface of the second modified film 22 and the upper surface of the first modified film 21, forming the preceding recess.

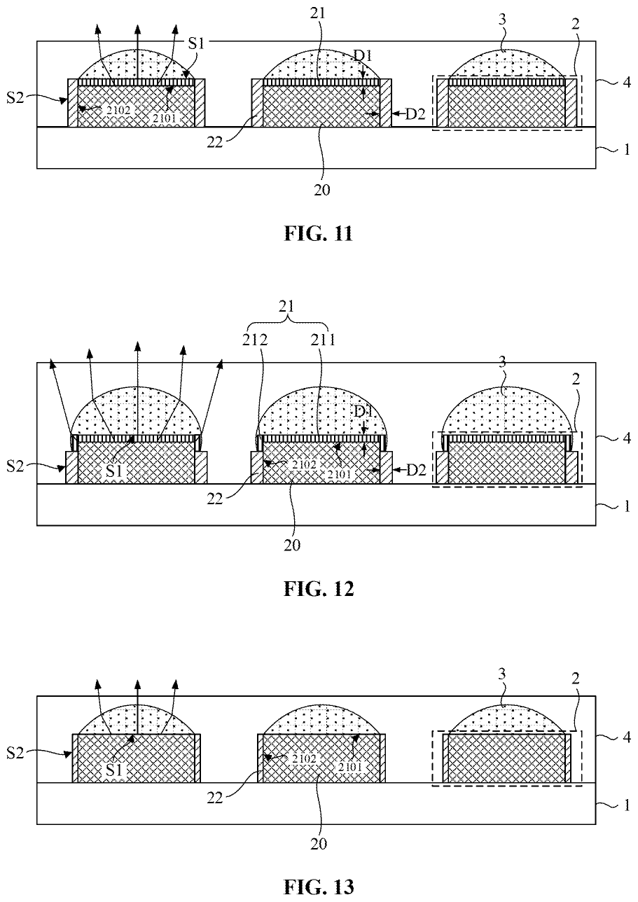

FIG. 11 is another section view of a display panel according to an embodiment of the present disclosure. FIG. 12 is another section view of a display panel according to an embodiment of the present disclosure. Referring to FIGS. 11 and 12, in one or more embodiments, the thickness of the second modified film 22 in the direction perpendicular to the lateral surface 2102 is D2, and the thickness of the first modified film 21 in the direction perpendicular to the top surface 2101 is D1. D2>D1.

In the embodiments, the second modified film 22 is located on the lateral surface 2102 of the light-emitting element 20, and the first modified film 21 is located on the top surface 2101 of the light-emitting element 20 and even extends to the lateral surface 2102. Based on this, the thickness D2 of the second modified film 22 is set to be greater than the thickness D1 of the first modified film 21, so that a step difference exists at the contact position between the second modified film layer 22 and the first modified film layer 21. It is to be understood that in the embodiments, that the second modified film 22 is located on the lateral surface 2102 and the first modified film 21 is located on the top surface 2101 and even extends to the lateral surface 2102 means that the vertex angle or lateral surface 2102 of the light-emitting element 20 may exist at the contact position between the first modified film 21 and the second modified film 22. The step difference at the contact position between the second modified film 22 and the first modified film 21 can provide a vertical upward supporting force for the microlens 3 located on the surface of the first modified film 21 and extending to the contact position, preventing the material of the microlens 3 from dispersing from the lateral surface 2102 of the light-emitting element 20 due to gravity. Thus, when the microlens 3 is prepared, the second modified film 22 can effectively limit the material of the microlens 3 onto the surface of the first modified film 21, that is, the first surface, due to the dual effects of hydrophilicity or hydrophobicity and the step difference, achieving the automatic alignment function of the microlens 3.

Continuing to refer to FIG. 5, in some embodiments, the thickness D1 of the first modified film 21 in the direction perpendicular to the plane where the circuit substrate 1 is located is less than 10 nm.

In the embodiments of the present disclosure, first modified films 21 may be formed in batches by using processes such as spraying or brushing on the multiple light-emitting elements 20 bonded to the circuit substrate 1. Moreover, after the preparation of the first modified film 21 is completed, the circuit substrate 1 is immersed in the material solution of the second modified film 22 so that the second modified film 22 can be attached to the lateral surface 2102 of the light-emitting element 20. The first modified film 21 is formed on the top surface 2101, one of the first modified film 21 or the second modified film 22 is hydrophilic, and the other of the first modified film 21 or the second modified film 22 is hydrophobic, so the second modified film 22 cannot be attached to the top surface 2101 of the light-emitting element 20. Thus, the preparation of the second modified film 22 on the lateral surface 2102 of the light-emitting element 20 can be completed. When the first modified film 21 is formed by spraying or brushing, there are certain requirements for the attachment surface of the film material. For the convenience of understanding, the following explanation uses spraying as an example: The spraying method determines that the film material is more attached to the surface perpendicular to the spraying direction. That is, when the first modified film 21 is prepared on the top surface 2101 of the light-emitting element 20, it is required to spray towards the direction perpendicular to the top surface 2101 of the light-emitting element 20. There are gaps between the light-emitting elements 20; therefore, to ensure that the sprayed film material breaks at the gaps between the light-emitting elements 20 and remains on only the top surface 2101 of each light-emitting element 20, the thickness of the spraying requires to be controlled. In this manner, a structure similar to a connecting bridge between the light-emitting elements 20 can be prevented from occurring due to excessive thickness of spraying on the film material. Based on experimental verification, in the embodiment of the present disclosure, the thickness of the sprayed film material can be set less than 10 nm. This can ensure that first modified films 21 on the top surfaces 2101 of the light-emitting elements 20 are broken so that a light-emitting element 20 with only the top surface 2101 covered by the first modified film 21 can be prepared. The same goes to brushing. When the brushing thickness is thick, the film material on the top surfaces 2101 of adjacent light-emitting elements 20 forms a connecting bridge. Therefore, that the thickness of the film material, that is, the thickness D1 of the first modified film 21, is controlled to be less than 10 nm can ensure that first modified films 21 on the top surfaces 2101 of the light-emitting elements 20 are broken so that a light-emitting element 20 with only the top surface 2101 covered by the first modified film 21 can be prepared.

During the process of preparing the first modified film 21 by using a spraying or brushing process, due to the preparation precision, when the film material is formed on the top surface 2101 of the light-emitting element 20, the film material is also attached to the top surface 2101 of the light-emitting element 20 adjacent to the top surface 2101. That is, a first modified film 21 that is attached to both the top surface 2101 and the lateral surface 2102 of the light-emitting element 20 is formed. The first modified film 21 that covers only the top surface 2101 of the light-emitting element 20 and the first modified film 21 that covers both the top surface 2101 and part of the lateral surface 2102 of the light-emitting element 20 can both have a hydrophilic or hydrophobic surface—the first surface S1 and can both achieve the automatic alignment function of the microlens 3.

The preceding solution of preparing the first modified film 21 and the second modified film 22 is to transfer the light-emitting elements 20 in batches to the circuit substrate 1 and form the first modified film 21 and the second modified film 21 on the surfaces of the light-emitting element 20. According to the solutions, the surfaces of the light-emitting elements 20 are modified in batches, which can greatly improve the efficiency of surface modification of the light-emitting element 20 and save cost and time. This solution is one possible implementation of the present disclosure. Other methods may be used to prepare first modified films 21 and second modified films 22 in batches on the top surfaces 2101 of the light-emitting elements 20 according to the actual situation. In one or more embodiments, before transferring the light-emitting element 20 to the circuit substrate 1, surface modification can also be performed on the light-emitting element 20 to prepare two modified films to form the light-emitting component 2 and transfer the light-emitting component 2 to the circuit substrate 1.

The preceding embodiments provides a solution of preparing modified films that are different in hydrophilicity or hydrophobicity to form the first surface and the second surface. Embodiments of the present disclosure also provide other implementations of forming the first surface and the second surface.

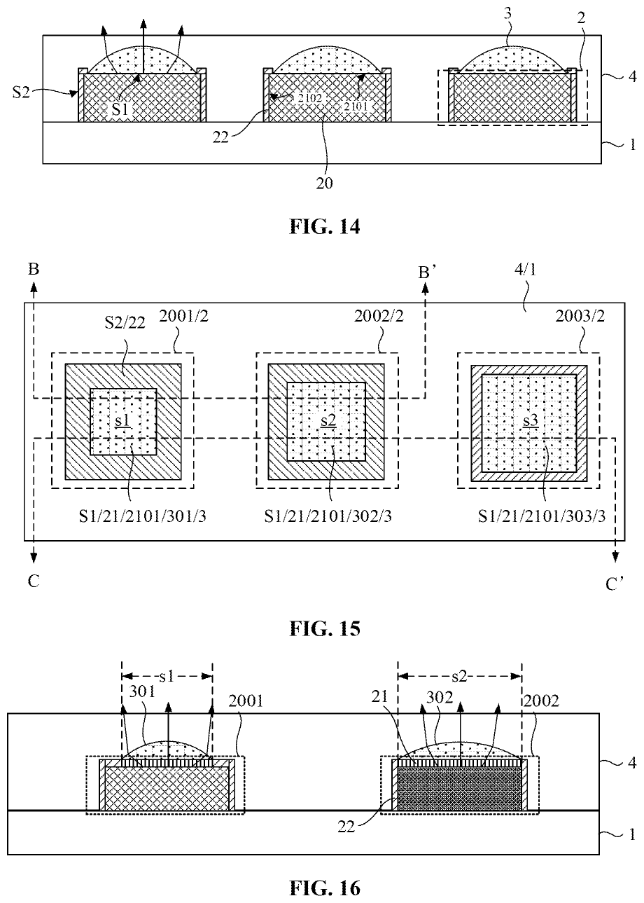

FIG. 13 is another section view of a display panel according to an embodiment of the present disclosure. FIG. 14 is another section view of a display panel according to an embodiment of the present disclosure. Referring to FIGS. 13 and 14, in some embodiments, it is feasible to modify the top surface 2101 of the light-emitting element 20 to ensure that the first surface S1 is formed on at least part of the top surface 2101 of the light-emitting element 20. In an example in which the top surface 2101 of the light-emitting element 20 is made hydrophilic, the top surface 2101 of the light-emitting element 20 is modified to a hydrophilic surface, that is, a first surface S1, by using plasma or ultraviolet light. In the embodiments, the second surface S2 can still be formed by preparing the second modified film 22. For details, see the preparation method of each previous embodiment. The details are not described herein again.

Referring to FIG. 13, the first surface S1 is formed by modifying the top surface 2101 of the light-emitting element 20, and the second surface S2 is formed by preparing the second modified film 22 on the lateral surface 2102 of the light-emitting element 20. In the direction parallel to the top surface 2101 of the light-emitting element 20, the second modified film 22 covering the lateral surface 2102 of the light-emitting element 20 has a certain thickness and thus has a step difference surface. The step difference surface belongs to the second surface S2 that surrounds the first surface S1 on the top surface 2101 of the light-emitting element 20. Therefore, when the microlens 3 is prepared, when the material of the microlens 3 is attached to the first surface S1 and extends to the contact position between the first surface S1 and the second surface S2, the step difference surface of the second modified film 22 can prevent the material of the microlens 3 from dispersing from the lateral surface 2102, better limiting the position of the microlens 3 and enabling the automatic alignment function of the microlens 3 more effectively.

Referring to FIG. 14, the first surface S1 is formed by modifying the top surface 2101 of the light-emitting element 20, and the second surface S2 is formed by preparing the second modified film 22 on the surface of the light-emitting element 20. Thus, there is a step difference at the contact position between the first surface S1 and the second surface S2. According to the recess principle described earlier, the step difference can better limit the material of the microlens 3 onto the first surface S1 when the microlens 3 is prepared, enabling the automatic alignment function of the microlens 3 more effectively.

The preceding embodiments provide implementations of forming the first surface and the second surface on the surfaces of the light-emitting element. The position of the microlens can be limited based on hydrophilicity or hydrophobicity of the first surface or the second surface. In addition to the preceding implementations, other implementations can be used to form the first surface and the second surface which is not limited in the present disclosure. Moreover, different preparation solutions of forming the first surface and the second surface that are different in hydrophilicity or hydrophobicity fall within the scope of the present application.

Considering that automatic alignment of the microlens and the shape of the microlens are mainly lies in the first surface and the second surface, the present disclosure provides different implementations for the shape of the microlens. The details are described below.

FIG. 15 is another diagram illustrating partial structure of a display panel according to an embodiment of the present disclosure. Referring to FIG. 15, in one or more embodiments, the multiple light-emitting components 2 include a first-color light-emitting component 2001 and a second-color light-emitting component 2002. The first-color light-emitting component 2001 and the second-color light-emitting component 2002 are light-emitting components of different colors. The area of the orthographic projection of the first modified film 21 of the first-color light-emitting component 2001 on the plane where the circuit substrate 1 is located is s1, and the area of the orthographic projection of the first modified film 21 of the second-color light-emitting component 2002 on the plane where the circuit substrate 1 is located is s2, where s1<s2.

Due to that s1<s2, light-emitting components of different colors are different in terms of the area of the orthographic projection of the first modified film 21 of the light-emitting component on the plane where the circuit substrate 1 is located, thereby ensuring that microlenses 3 formed on light-emitting components of different colors have different bottom areas to adapt to different light emission situations of light-emitting components of various colors, such as different luminous efficiencies and different angle-of-view brightnesses. In this manner, microlenses 3 in matching shapes are formed to overcome different light emission situations of light-emitting components of different colors so that light-emitting components of different colors have the same brightness, ensuring the display uniformity of the display panel and preventing color cast.

The first-color light-emitting component 2001 may be a green light-emitting component. The second-color light-emitting component 2002 may be a red light-emitting component or a blue light-emitting component. The solution of this embodiment is described in an example in which the first-color light-emitting component 2001 is a green light-emitting component, and the second-color light-emitting component 2002 is a red light-emitting component. There is a difference in luminous efficiency between existing green light-emitting elements and red light-emitting elements. The luminous efficiency of existing green light-emitting elements is higher than that of existing red light-emitting elements. In view of the difference in luminous efficiency, to ensure that light-emitting components 2 of different colors have uniform brightness, in the embodiments, the area s2 of the orthographic projection of the first modified film 21 of the second-color light-emitting component 2002 (that is, red light-emitting component) on the plane where the circuit substrate 1 is located is set greater than the area s1 of the orthographic projection of the first modified film 21 of the first-color light-emitting component 2001 (that is, green light-emitting component), ensuring that the microlens 3 formed on the first modified film 21 of the second-color light-emitting component 2002 (that is, red light-emitting component) has a larger bottom area to gather more exit light from the second-color light-emitting component 2002 (that is, red light-emitting component) before focusing and outputting the gathered exit light. This is equivalent to increasing the amount of light emitted from the front angle of view of the second-color light-emitting component 2002 (that is, red light-emitting component) having a lower luminous efficiency, thereby increasing the light utilization rate of the red light-emitting component, making up for the problem of low luminous efficiency of the red light-emitting component, improving the brightness of the red light-emitting component, overcoming the difference in brightness among light-emitting components of different colors caused by different luminous efficiencies, and thus preventing color cast.

Additionally, the same microlens has different focal lengths for light of different wavelengths. The longer the wavelength, the longer the focal length of light. Focal length represents the ability to focus light. That is, the longer the wavelength, the weaker the light focusing ability. According to a red light wavelength range of 625˜740 nm and a green light wavelength range of 577˜492 nm, the red light wavelength is greater than the green light wavelength. That is, the microlens has a weaker ability to focus light emitted from the red light-emitting component than light emitted from the green light-emitting component. In view of the wavelength of exit light, to ensure that light-emitting components 2 of different colors have uniform brightness, in the embodiments, the area s2 of the orthographic projection of the first modified film 21 of the second-color light-emitting component 2002 (that is, red light-emitting component) on the plane where the circuit substrate 1 is located is set greater than the area s1 of the orthographic projection of the first modified film 21 of the first-color light-emitting component 2001 (that is, green light-emitting component), ensuring that the microlens 3 corresponding to the second-color light-emitting component 2002 (that is, red light-emitting component) has a larger bottom area to focus more exit light from the red light-emitting component, thereby increasing the front-angle-of-view brightness of the red light-emitting component, making up for the problem of low ability of the microlens to focus light emitted from the red light-emitting component, overcoming the difference in brightness among light-emitting components of different colors caused by different effects of focusing of exit light having different wavelengths, and thus preventing color cast.

Light-emitting elements of different colors are different in angle-of-view brightness. For example, the angle-of-view brightness of the green light-emitting element is higher than the angle-of-view brightness of the red light-emitting element. This is because the green light-emitting element is larger in the projection area of exit light. Thus, the green light-emitting element can emit more angle-of-oblique-view light and can emit more divergent light. In view of the difference in angle-of-view brightness, the first-color light-emitting component 2001 may be a red light-emitting component or a blue light-emitting component, and the second-color light-emitting component 2002 may be a green light-emitting component. The following description uses an example in which the first-color light-emitting component 2001 is a red light-emitting component, and the second-color light-emitting component 2002 is a green light-emitting component. In the embodiments, the area s2 of the orthographic projection of the first modified film 21 of the second-color light-emitting component 2002 (that is, green light-emitting component) on the plane where the circuit substrate 1 is located is set greater than the area s1 of the orthographic projection of the first modified film 21 of the first-color light-emitting component 2001 (that is, red light-emitting component), ensuring that the microlens 3 formed on the first modified film 21 of the second-color light-emitting component 2002 (that is, green light-emitting component) has a larger bottom area to focus light emitted from the angle of oblique view of the second-color light-emitting component 2002 (that is, green light-emitting component) into light emitted from the front angle of view of the second-color light-emitting component 2002. This is equivalent to enabling more exit light of the second-color light-emitting component 2002 (that is, green light-emitting component) having a higher front-of-view brightness to be output from the front view of angle, thereby reducing light emitted from the angle of oblique view, reducing the projection area of the exit light, better focusing light, making up for the problem of high angle-of-view brightness of the green light-emitting component, improving the amount of front-angle-of-view light of the green light-emitting component, and overcoming the difference in brightness among light-emitting components of different colors caused by the difference in angle-of-view brightness, and thus preventing color cast.

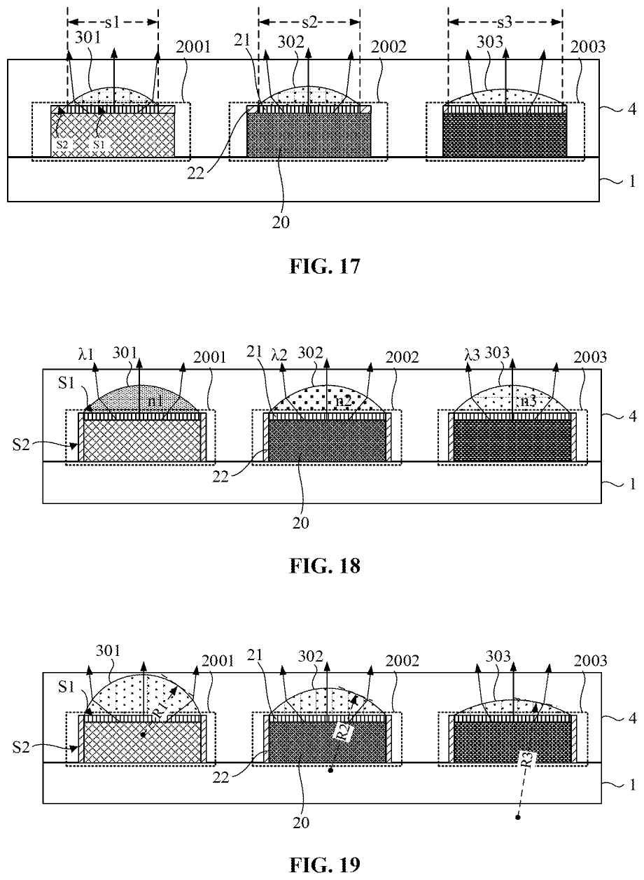

FIG. 16 is a section view taken along BB′ of the display panel shown in FIG. 15. FIG. 17 is a section view taken along CC′ of the display panel shown in FIG. 15. Referring to FIGS. 15 and 16, in one or more embodiments, the following arrangement may be configured: in the first-color light-emitting component 2001, the first modified film 21 and the second modified film 22 are both located on the top surface 2101, and the orthographic projection of the second modified film 22 on the plane where the circuit substrate 1 is located surrounds the orthographic projection of the first modified film 21 on the plane where the circuit substrate 1 is located; and in the second-color light-emitting component 2002, the first modified film 21 is located on the top surface 2101, the orthographic projection of the first modified film 21 on the plane where the circuit substrate 1 is located coincides with the orthographic projection of the top surface 2101 on the plane where the circuit substrate 1 is located, and the second modified film 22 is located on the lateral surface 2102. In one or more embodiments, referring to FIGS. 15 and 17, the following arrangement may be performed: in the first-color light-emitting component 2001 and the second-color light-emitting component 2002, the first modified film 21 and the second modified film 22 are both located on the top surface 2101, and the orthographic projection of the second modified film 22 on the plane where the circuit substrate 1 is located surrounds the orthographic projection of the first modified film 21 on the plane where the circuit substrate 1 is located.

FIG. 16 and FIG. 17 each shows a solution of differentially arranging the area of the first modified film on light-emitting components of different colors. For the display panel shown in FIGS. 15 and 16, to configure the area of the first modified film 21 of the first-color light-emitting component 2001 to be smaller and the area of the first modified film 21 of the second-color light-emitting component 2002 to be larger, the second modified film 22 of the first-color light-emitting component 2001 is disposed on the top surface 2101 of the light-emitting element 20 to surround the first modified film 21 on the top surface 2101 of the light-emitting element 20. The area of the top surface 2101 of the light-emitting element 20 is limited, so the area of the first modified film 21 is compressed. In the second-color light-emitting component 2002, the second modified film 22 is disposed on the lateral surface 2102 of the light-emitting element 20 so that the first modified film 21 can completely occupy the area of the top surface 2101 of the light-emitting element 20; therefore, the area of the first modified film 21 is larger, so the microlens 3 on the first modified film 21 can have a larger bottom area, increasing focusing of light. In this manner, a brightness balance is achieved among light-emitting components 2 of different colors. For the display panel shown in FIGS. 15 and 17, to configure the area of the first modified film 21 of the first-color light-emitting component 2001 to be smaller and the area of the first modified film 21 of the second-color light-emitting component 2002 to be larger, the first modified film 21 and the second modified film 22 of the first-color light-emitting component 2001 are both disposed on the top surface 2101 of the light-emitting element 20; in addition, the area of the first modified film 21 is differentially designed based on the color of the light-emitting component 2. The area of the first modified film 21 of the first-color light-emitting component 2001 is configured to be smaller, and the area of the first modified film 21 of the second-color light-emitting component 2002 is configured to be larger, so the microlens 3 on the second-color light-emitting component 2002 can have a larger bottom area, increasing focusing of light. In this manner, a brightness balance is achieved among light-emitting components 2 of different colors.

Continuing to refer to FIGS. 15 and 17, in the embodiments, the light-emitting component 2 may also include a third-color light-emitting component 2003. Based on that the first-color light-emitting component 2001 is a green light-emitting component, and the second-color light-emitting component 2002 is a red light-emitting component, the third-color light-emitting component 2003 may be a blue light-emitting component. Considering that the luminous efficiency of blue light-emitting components is lower than that of red light-emitting components, to achieve a brightness balance between light-emitting components 2 of different colors, the area s2 of the orthographic projection of the first modified film 21 of the second-color light-emitting component 2002 (that is, red light-emitting component) on the plane where the circuit substrate 1 is located is set less than the area s3 of the orthographic projection of the first modified film 21 of the third-color light-emitting component 2003 (that is, blue light-emitting component) on the plane where the circuit substrate 1 is located. The principle for differentially setting the projection area of the first modified film 21 of the red second-color light-emitting component 2002 and the projection area of the first modified film 21 of the blue third-color light-emitting component 2003 is the same as the preceding principle for differentially setting the projection area of the first modified film 21 of the green first-color light-emitting component 2001 and the projection area of the first modified film 21 of the red second-color light-emitting component 2002.

Similarly, considering that the angle-of-view brightness of the blue light-emitting component is lower than that of the red light-emitting component, based on that the first-color light-emitting component 2001 is a red light-emitting component, and the second-color light-emitting component 2002 is a green light-emitting component, the third-color light-emitting component 2003 may be a blue light-emitting component. To overcome the brightness difference caused by the angle-of-view brightness difference between light-emitting components 2 of different colors, the area s1 of the orthographic projection of the first modified film 21 of the first-color light-emitting component 2001 (that is, red light-emitting component) on the plane where the circuit substrate 1 is located is set greater than the area s3 of the orthographic projection of the first modified film 21 of the third-color light-emitting component 2003 (that is, blue light-emitting component) on the plane where the circuit substrate 1 is located. Similarly, the principle for differentially setting the projection area of the first modified film 21 of the red first-color light-emitting component 2001 and the projection area of the first modified film 21 of the blue third-color light-emitting component 2003 is the same as the preceding principle for differentially setting the projection area of the first modified film 21 of the red first-color light-emitting component 2001 and the projection area of the first modified film 21 of the green second-color light-emitting component 2002.

FIG. 18 is another section view of a display panel according to an embodiment of the present disclosure. FIG. 19 is another section view of a display panel according to an embodiment of the present disclosure. Referring to FIGS. 18 and 19, in one or more embodiments, the multiple light-emitting components 2 include a first-color light-emitting component 2001 and a second-color light-emitting component 2002, where the exit light center wavelength λ1 of the first-color light-emitting component 2001 is greater than the exit light center wavelength λ2 of the second-color light-emitting component 2002; and the multiple microlenses 3 include a first microlens 301 and a second microlens 302, where the first microlens 301 is disposed on the first surface S1 of the first-color light-emitting component 2001, and the second microlens 302 is disposed on the first surface S1 of the second-color light-emitting component 2002. The refractive index n1 of the first microlens 301 is greater than the refractive index n2 of the second microlens 302, as shown in FIG. 18; or, the radius R1 of curvature of the surface of the first microlens 301 facing away from the circuit substrate 1 is less than the radius R2 of curvature of the surface of the second microlens 302 facing away from the circuit substrate 1, as shown in FIG. 19.

As mentioned earlier, the microlens has different focal lengths for light of different wavelengths. The longer the wavelength, the longer the focal length. Focal length represents the ability to focus light. That light having a longer wavelength has a longer focal length means that the microlens can worse focus light having a longer wavelength. The display panel includes light-emitting components of two colors, that is, the first-color light-emitting component 2001 and the second-color light-emitting component 2002. The exit light center wavelength λ1 of the first-color light-emitting component 2001 is greater than the exit light center wavelength λ2 of the second-color light-emitting component 2002. To achieve a balance between the effects of focusing of exit light of the light-emitting components of the two colors by microlenses, it is feasible in the present disclosure to differentially design microlenses corresponding to the light-emitting components of the two colors, for example, by relatively increasing the focusing ability of the first microlens 301 corresponding to the first-color light-emitting component 2001 having a relatively larger exit light center wavelength and relatively decreasing the focusing ability of the first microlens 301 corresponding to the first-color light-emitting component 2001 having a relatively smaller exit light center wavelength. In one or more embodiments, as shown in FIG. 18, it is feasible to prepare the first microlens 301 by using the material having a larger refractive index and prepare the second microlens 302 by using the material having a smaller refractive index. It is to be understood that the refractive index of a lens is one of the key factors affecting the focusing ability of the lens. On the premise that the refractive index of the exterior (which means the planarization layer here) remains unchanged, an increase in the refractive index of a microlens enables an increase in the focusing ability of the microlens, that is, the first microlens 301 having a larger refractive index has a larger focusing ability than the second microlens 302. This can reduce the difference between the effect of focusing of exit light of the first-color light-emitting component 2001 by the first microlens 301 and the effect of focusing of exit light of the second-color light-emitting component 2002 by the second microlens 302, make the light-emitting components of the two colors have the same luminous effect, and prevent the problems of nonuniform display and color cast caused by different luminous effects.

In one or more embodiments, as shown in FIG. 19, based on that the microlens of the present disclosure is basically a planoconvex lens, it is feasible to configure a smaller radius R1 of curvature for the convex surface of the first microlens 301 corresponding to the first-color light-emitting component 2001 having a larger exit light center wavelength and configure a larger radius R2 of curvature for the convex surface of the second microlens 302 corresponding to the second-color light-emitting component 2002 having a smaller exit light center wavelength. The convex surface herein refers to the surface of the microlens facing away from the circuit substrate 1. It is to be understood that the radius of curvature of a lens is one of the key factors affecting the focusing ability of the lens. The first microlens 301 is configured to have a smaller radius of curvature than the second microlens 302 and thus is more planoconvex. This can also increase the focusing ability of the first microlens 301, reduce the difference between the effect of focusing of exit light of the first-color light-emitting component 2001 by the first microlens 301 and the effect of focusing of exit light of the second-color light-emitting component 2002 by the second microlens 302, make the light-emitting components of the two colors have the same luminous effect, and prevent the problems of nonuniform display and color cast caused by different luminous effects.

In addition to the difference between the ability to focus light of one wavelength by one microlens and the ability to focus light of another wavelength by another microlens, a difference in luminous efficiency occurs among light-emitting components of different colors. In the embodiments, the exit light center wavelength λ1 of the first-color light-emitting component 2001 is greater than the exit light center wavelength λ2 of the second-color light-emitting component 2002, so the first-color light-emitting component 2001 may be construed as a red light-emitting component, and the second-color light-emitting component 2002 may be construed as a green light-emitting component. According to the preceding description, the light exit efficiency of the red light-emitting component is lower than that of the green light-emitting component. Thus, in the embodiments, the refractive index n1 of the first microlens 301 corresponding to the first-color light-emitting component 2001 (that is, red light-emitting component) is set relatively large, and/or the radius of curvature of the convex surface of the first microlens 301 is set relatively small. This can increase the ability of the first microlens 301 to focus red light, make up for the problem of low luminous efficiency of the red light-emitting component, reduce the difference between the effect of focusing of exit light of the first-color light-emitting component 2001 by the first microlens 301 and the effect of focusing of exit light of the second-color light-emitting component 2002 by the second microlens 302, make the light-emitting components of the two colors have the same luminous effect, and prevent the problems of nonuniform display and color cast caused by different luminous effects.

When it is considered that the difference in angle-of-view brightnesses of light-emitting components of different colors may cause the problem of ununiform brightness in the proceeding embodiments, based on the first-color light-emitting component 2001 and the second-color light-emitting component 2002, that that the exit light center wavelength λ1 of the first-color light-emitting component 2001 is greater than the exit light center wavelength λ2 of the second-color light-emitting component 2002, and that red light has a wavelength range of 625˜740 nm while blue light has a wavelength range of 400˜500 nm (that is, red light has a longer wavelength than blue light), the first-color light-emitting component 2001 may be construed as a red light-emitting component while the second-color light-emitting component 2002 may be construed as a blue light-emitting component. The red light-emitting element has a higher angle-of-view brightness, a larger exit light projection area, emits more angle-of-oblique-view light, and emits more divergent light than the blue light-emitting element. In the embodiments, the refractive index n1 of the first microlens 301 corresponding to the first-color light-emitting component 2001 (that is, red light-emitting component) is set relatively large, and/or the radius of curvature of the convex surface of the first microlens 301 is set relatively small. This can relatively increase the ability of the first microlens 301 to focus red light, make up for the problem of higher angle-of-view brightness of the red light-emitting component than the blue light-emitting component, reduce the difference between the effect of focusing of exit light of the first-color light-emitting component 2001 by the first microlens 301 and the effect of focusing of exit light of the second-color light-emitting component 2002 by the second microlens 302, make the light-emitting components of the two colors have the same luminous effect, and prevent the problems of nonuniform display and color cast caused by different luminous effects.

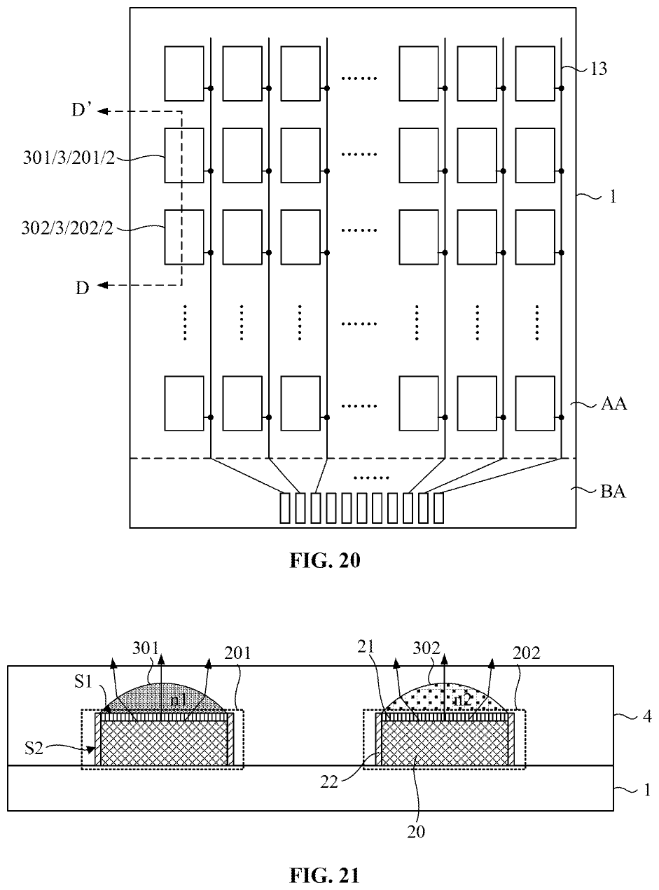

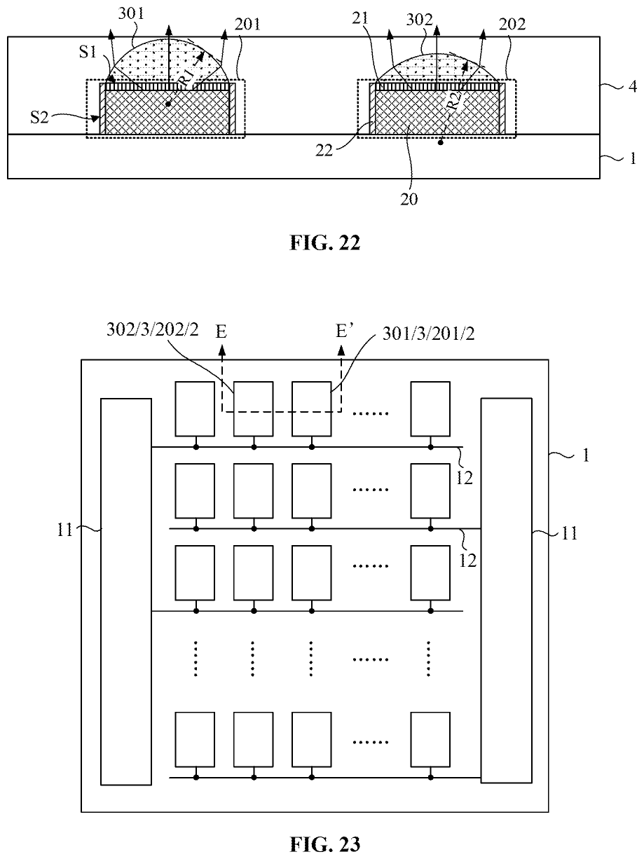

FIG. 20 is another diagram illustrating the structure of a display panel according to an embodiment of the present disclosure. FIG. 21 is a section view taken along DD′ of the display panel shown in FIG. 20. FIG. 22 is another section view taken along DD′ of the display panel shown in FIG. 20. Referring to FIGS. 20 to 22, in one or more embodiments, the circuit substrate 1 includes a bonding region BA configured to bond a driver chip and/or a flexible wiring board (not shown).

The multiple light-emitting components 2 include a first light-emitting component 201 and a second light-emitting component 202. The distance between the first light-emitting component 201 and the bonding region BA is greater than the distance between the second light-emitting component 202 and the bonding region BA.

The multiple microlenses 3 include a first microlens 301 and a second microlens 302. The first microlens 301 is disposed on the first surface S1 of the first light-emitting component 201. The second microlens 302 is disposed on the first surface S1 of the second light-emitting component 202.

The refractive index n1 of the first microlens 301 is greater than the refractive index n2 of the second microlens 302, as shown in FIG. 21; and/or, the radius R1 of curvature of the surface of the first microlens 301 facing away from the circuit substrate 1 is less than the radius R2 of curvature of the surface of the second microlens 302 facing away from the circuit substrate 1, as shown in FIG. 22.

First, the light-emitting component 2 is disposed in the display region AA of the circuit substrate 1, a driver circuit and data signal lines 13 connected to the driver circuit are disposed in the display region AA, the data signal lines 13 provide data signals for the driver circuit, and the driver circuit drives a light-emitting component 2 according to a data signal corresponding to the light-emitting component 2. The data signals are provided by the external driver chip or the flexible wiring board. To implement data signal input, a bonding region BA is disposed on the circuit substrate 1 to bond the external driver chip or the flexible wiring board. A bonding pad is disposed in the bonding region BA. The bonding pad is connected to the data signal lines 13 through fan-out lines so that the driver chip provides data signals to the driver circuit through the bonding pad, the fan-out lines, and the data signal lines 13 in sequence to drive the light-emitting components 2. For each data signal line 13, a data signal line 13 has a certain length and thus has a certain impedance, making attenuated a data signal transmitted through the data signal line 13, and making light-emitting components 2 at different positions of the data signal line 13 have different light emission driving forces. The more the data signal attenuates, the lower the brightness of the light-emitting components 2. The farther a light-emitting component 2 is from the bonding region BA, the longer the data signal received by the corresponding driver circuit is transmitted on the data signal line 13, the greater the attenuation of the data signal, and the smaller the brightness of the light-emitting component 2.

Based on this, in the embodiments, the microlenses corresponding to any two light-emitting components 2 having different distances from the bonding region BA are differentially designed. For the first light-emitting component 201 that is relatively far from the bonding region BA, the focusing effect of the corresponding first microlens 301 may be relatively increased, thereby relatively improving the brightness of the first light-emitting component 201 and making up for the negative impact of data signal attenuation on the brightness. In one or more embodiments, as shown in FIG. 21, it is feasible to prepare the first microlens 301 by using the material having a larger refractive index and prepare the second microlens 302 by using the material having a smaller refractive index. An increase in the refractive index of a microlens enables an increase in the focusing ability of the microlens. This makes the first microlens 301 have a higher light focusing ability and makes up for the lower brightness of the first light-emitting component 201 due to its longer distance from the bonding region BA. In one or more embodiments, as shown in FIG. 22, it is feasible to configure a smaller radius R1 of curvature for the convex surface of the first microlens 301 and configure a larger radius R2 of curvature for the convex surface of the second microlens 302. The first microlens 301 is configured to have a smaller radius of curvature than the second microlens 302 and thus is more planoconvex. This can also increase the light focusing ability of the first microlens 301 to make up for the lower brightness of the first light-emitting component 201 due to its longer distance from the bonding region BA.

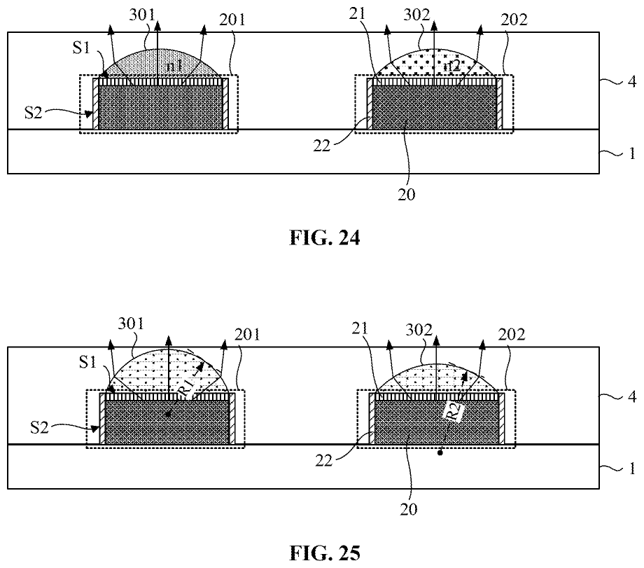

FIG. 23 is another diagram illustrating the structure of a display panel according to an embodiment of the present disclosure. FIG. 24 is a section view taken along EE′ of the display panel shown in FIG. 23. FIG. 25 is another section view taken along EE′ of the display panel shown in FIG. 23. Referring to FIGS. 23 to 25, in one or more embodiments, the circuit substrate 1 includes gate driving circuits 11 and scan signal lines 12 electrically connected to the gate driving circuits 11, and light emitting components 2 arranged in sequence along the extension direction of a scan signal line 12 are coupled to the scan signal line 12.

Light-emitting components 2 coupled to the same scan signal line 12 include a first light-emitting component 201 and a second light-emitting component 202. Along the extension direction of the scan signal line 12, the distance between the first light-emitting component 201 and the gate driving circuit 11 is greater than the distance between the second light-emitting component 202 and the gate driving circuit 11.

The multiple microlenses 3 include a first microlens 301 and a second microlens 302. The first microlens 301 is disposed on the first surface S1 of the first light-emitting component 201. The second microlens 302 is disposed on the first surface S1 of the second light-emitting component 202.

The refractive index n1 of the first microlens 301 is greater than the refractive index n2 of the second microlens 302, and/or the radius R1 of curvature of the surface of the first microlens 301 facing away from the circuit substrate 1 is less than the radius R2 of curvature of the surface of the second microlens 302 facing away from the circuit substrate 1.

When the driver circuit on the circuit substrate 1 drives the light-emitting components 2 to emit light, not only data signals are required, scan signals also require address selection, so that the light-emitting components 2 can emit light in sequence to achieve screen refresh of the display panel. A scan signal is provided by a gate driving circuit 11 on the circuit substrate 1 and transmitted to each driver circuit through a scan signal line 12. Similar to transmission of a data signal by a data signal line 13, during transmission of a scan signal by a scan signal line 12, signal attenuation occurs due to impedance. This causes the driver circuit to charge insufficiently and thus causes light-emitting components 2 to have a lower brightness. Moreover, the further away from the gate driving circuit 11, the greater the signal attenuation, and the lower the brightness.

Based on this, in the embodiments, the microlenses corresponding to any two light-emitting components 2 having different distances from the gate driving circuit 11 are differentially designed. For the first light-emitting component 201 that is relatively far from the gate driving circuit 11, the focusing effect of the corresponding first microlens 301 may be relatively increased, thereby relatively improving the brightness of the first light-emitting component 201 and making up for the negative impact of data signal attenuation on the brightness. Referring to FIGS. 24 and 25, it is feasible to increase the light focusing ability of the first microlens 301 by increasing the refractive index of the first microlens 301 or by increasing the radius R1 of curvature of the convex surface of the first microlens 301. For the principle used here, see each previous embodiment.

It is to be noted that the differentiated design of the first microlens corresponding to the first-color light-emitting component and the second microlens corresponding to the second-color light-emitting component and the differentiated design of the first microlens corresponding to the first light-emitting component and the second microlens corresponding to the second light-emitting component are both the differentiated design of the light focusing abilities of the two microlenses. For example, in the embodiments, two microlenses having different refractive indexes may be prepared by using different microlens materials, by doping or not doping refractive index adjusting materials in the same microlens material, or by using refractive index adjusting materials having different doping concentrations.

In the embodiments, it is feasible to differentially design the radiuses of curvature of the convex surfaces by perform the following configurations: The area of the orthographic projection of the first surface S1 of the first-color light-emitting component 2001 or the first light-emitting component 201 corresponding to the first microlens 301 on the plane where the circuit substrate 1 is located is configured less than the area of the orthographic projection of the first surface S1 of the second-color light-emitting component 2002 or the second light-emitting component 202 corresponding to the second microlens 302 on the plane where the circuit substrate 1 is located, and the volume of the first microlens 301 is configured equal to the volume of the second microlens 302; or the area of the orthographic projection of the first surface S1 of the first-color light-emitting component 2001 or the first light-emitting component 201 corresponding to the first microlens 301 on the plane where the circuit substrate 1 is located is configured equal to the area of the orthographic projection of the first surface S1 of the second-color light-emitting component 2002 or the second light-emitting component 202 corresponding to the second microlens 302 on the plane where the circuit substrate 1 is located, and the volume of the first microlens 301 is configured greater than the volume of the second microlens 302.

The area of the orthographic projection on the plane where the circuit substrate 1 is located represents the bottom area of the microlens and also represents the area of the first surface S1. When preparing the two microlenses, it is feasible to make the microlenses have different lengths and have different radiuses of curvature of the convex surfaces by using the same quantity of materials to prepare the microlenses and differentially designing the areas of the first surfaces S1 of the microlenses (that is, differentially designing the bottom areas of the microlenses) or to make the microlenses have different lengths and have different radiuses of curvature of the convex surfaces by using different quantities of materials to form the microlenses of different volumes and making the first surfaces S1 of the microlenses have the same area (that is, have the same bottom area).

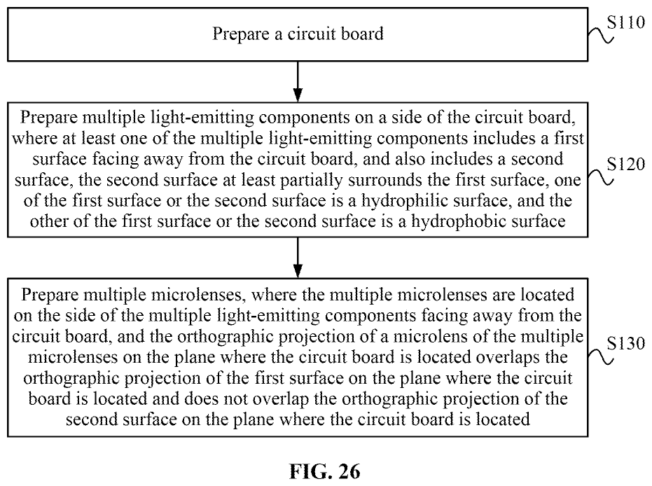

Embodiments of the present disclosure also provide a preparation method of a display panel. FIG. 26 is a flowchart of a preparation method of a display panel according to an embodiment of the present disclosure. Referring to FIG. 26, this preparation method of a display panel is used for preparing the display panel of any previous embodiment of the present disclosure. The method includes S110, S120, and S130.

In S110, a circuit substrate is prepared.

In S120, multiple light-emitting components are prepared on a side of the circuit substrate, where at least one of the multiple light-emitting components includes a first surface facing away from the circuit substrate, and also includes a second surface, the second surface at least partially surrounds the first surface, one of the first surface or the second surface is a hydrophilic surface, and the other of the first surface or the second surface is a hydrophobic surface.

In S130, multiple microlenses are prepared, where the multiple microlenses are located on the side of the multiple light-emitting components facing away from the circuit substrate, and the orthographic projection of a microlens of the multiple microlenses on the plane where the circuit substrate is located overlaps the orthographic projection of the first surface on the plane where the circuit substrate is located and does not overlap the orthographic projection of the second surface on the plane where the circuit substrate is located.

The method includes preparing the circuit substrate; preparing multiple light-emitting components on a side of the circuit substrate, where at least one of the multiple light-emitting components includes the first surface facing away from the circuit substrate includes the first surface includes the first surface, at least one of the multiple light-emitting components also includes the second surface, the second surface at least partially surrounds the first surface, one of the first surface or the second surface is a hydrophilic surface, and the other of the first surface or the second surface is a hydrophobic surface; and preparing multiple microlenses, where the multiple microlenses are located on the side of the multiple light-emitting components facing away from the circuit substrate, and the orthographic projection of the microlens on the plane where the circuit substrate is located overlaps the orthographic projection of the first surface on the plane where the circuit substrate is located and does not overlap the orthographic projection of the second surface on the plane where the circuit substrate is located. Thus, the first surface and the second surface that are different in hydrophilicity or hydrophobicity on the light-emitting elements enable position limitation and automatic alignment of the microlens when the microlens are prepared on the respective light-emitting elements, saving the trouble of aligning the microlens with the light exit sides of the light-emitting elements by the outside and preventing the problem of nonuniform display caused by an excessive difference between the positions of the light-emitting elements relative to the respective microlenses due to insufficient external alignment precision.

In one or more embodiments, S120 includes S121 and S122.

In S121, multiple light-emitting elements are transferred to the circuit substrate in batches.

In S122, surface modification is performed on the multiple light-emitting elements to form light-emitting components.

In the embodiments, the process of transferring the light-emitting elements 20 to the circuit substrate 1 in batches may be construed as aligning the light-emitting elements 20 on the circuit substrate 1 in batches and welding the electrodes of the light-emitting elements 20 to the circuit substrate 1 in a unified bonding process. In this manner, the light-emitting elements 20 are transferred in batches. After the light-emitting elements 20 are transferred in batches, the light-emitting element 20 does not have a first surface S1 and a second surface S2 that are different in hydrophilicity or hydrophobicity. At this time, surface modification of the light-emitting element 20 is required. Herein, the surface modification may be performed in one of following manners: modified films (such as the first modified film 21 and the second modified film 22) are formed on the surfaces of the light-emitting element 20; or the surfaces of the light-emitting element 20 are modified by using plasma or ultraviolet light. Batch transfer and batch modification can greatly improve the efficiency in preparing the light-emitting elements 20 and modifying the surfaces of the light-emitting elements 20, saving costs and time.

S122 includes S1221 and S1222.

In S1221, the first modified film is prepared on at least part of the top surface of the light-emitting element.

In S1222, the second modified film is prepared on the top surface and/or lateral surface of the light-emitting element, where one of the first modified film or the second modified film is made of a hydrophilic material, and the other of the first modified film or the second modified film is made of a hydrophobic material.

In S1221, the first modified film is prepared on at least part of the top surface 2101 of the light-emitting element by using a hydrophilic material or a hydrophobic material in a spraying or brushing process. In S1222, the prepared second modified film 22 and the first modified film 21 may use materials that are different in hydrophilicity or hydrophobicity. In S1221, the circuit substrate 1 bonded with the light-emitting element 20 may be immersed into a hydrophobic material or a hydrophilic material so that the hydrophobic material or hydrophilic material is attached to the remaining naked surface, namely the lateral surface 2102, of the light-emitting element 20 to form a second modified film 22 to make the light-emitting element 20 to form the light-emitting component 2 having a first surface S1 and a second surface S2 that are different in hydrophilicity or hydrophobicity, thereby facilitating preparation of the microlens on the light-emitting component 2.

The preparation method of the light-emitting component and the preparation method of the first modified film and the second modified film in a particular form are an embodiment of the present disclosure. The sequence and structure of the light-emitting component formed using these methods are one light-emitting component structure of the present disclosure. The first modified film and the second modified film may be prepared in the above form by using other methods, or in other forms by using other methods, or the light-emitting elements may be transferred and prepared according to other sequences, which are not limited in the embodiments. Illustratively, it is feasible to modify the surface of the light-emitting element to form the light-emitting component and transfer the light-emitting component to the circuit substrate. Illustratively, when the surface of the light-emitting element is modified, the first modified film and the second modified film provided in other display panel embodiments of the present disclosure may be designed and formed. For example, the first modified film and the second modified film are both located on the top surface of the light-emitting element, and the second modified film surrounds the first modified film.

In one or more embodiments, S130 includes S131 and S132.

In S131, microlens droplets are added to the first surface of the light-emitting component.

In S132, the microlens droplets are cured to form the microlens.

This embodiment essentially provides a preparation method in which droplets are added to the first surface S1 and cured to form the microlens 3. After an appropriate hydrophilic or hydrophobic material is selected, the microlens droplets have an affinity with the first surface S1 and a repellency against the second surface S2 so that the microlens droplets can automatically reside in the area where the first surface S1 is located and be cured to form the microlens 3, that is, implement the automatic alignment function.

It is feasible to form microlenses 3 having different refractive indexes by preparing microlens solutions having different refractive indexes or to form microlenses 3 whose convex surfaces have different radiuses of curvature by controlling the shapes of cured microlenses 3 by controlling the volumes of microlens droplets. In other words, the preparation method of microlenses facilitates differentiated designs of the microlenses, is simple and feasible to operate, can compensate for the problem of nonuniform light emission caused by differences in the features and positions of the light-emitting elements, and can improve the display effect of the display panel.

In view of the problem of the existing micro-LED display panel, the present disclosure also provides a display panel as described in the following.

The display panel includes a circuit substrate, multiple light-emitting components, and multiple microlenses. The multiple light-emitting components are located on a side of the circuit substrate. A light-emitting component of the multiple microlenses includes a first surface facing away from the circuit substrate. The light-emitting component and/or the circuit substrate includes a second surface. The second surface at least partially surrounds the first surface. One of the first surface or the second surface is a hydrophilic surface. The other of the first surface or the second surface is a hydrophobic surface. The orthographic projection of a microlens of the multiple microlenses on the plane where the circuit substrate is located does not overlap the orthographic projection of the first surface on the plane where the circuit substrate is located and overlaps the orthographic projection of the second surface on the plane where the circuit substrate is located.

In the embodiments, the display panel is prepared, where the light-emitting component includes the first surface and the second surface, one of the first surface or the second surface is a hydrophilic surface, and the other of the first surface or the second surface is a hydrophobic surface, the microlens has a stronger affinity with the second surface and has a repellency against the first surface after hydrophilicity or hydrophobicity of the first surface or the second surface is used and the material of the microlens is selected properly; and the material of the microlens resides on the second surface and repels the first surface to make the projection of the finally formed microlens overlap the projection of the second surface and not overlap the projection of the first surface. Thus, the first surface and the second surface that are different in hydrophilicity or hydrophobicity enables position limitation and automatic alignment of the microlens, preventing the problem of nonuniform display caused by an excessive difference between the positions of the light-emitting elements relative to the respective microlenses due to insufficient external alignment precision.

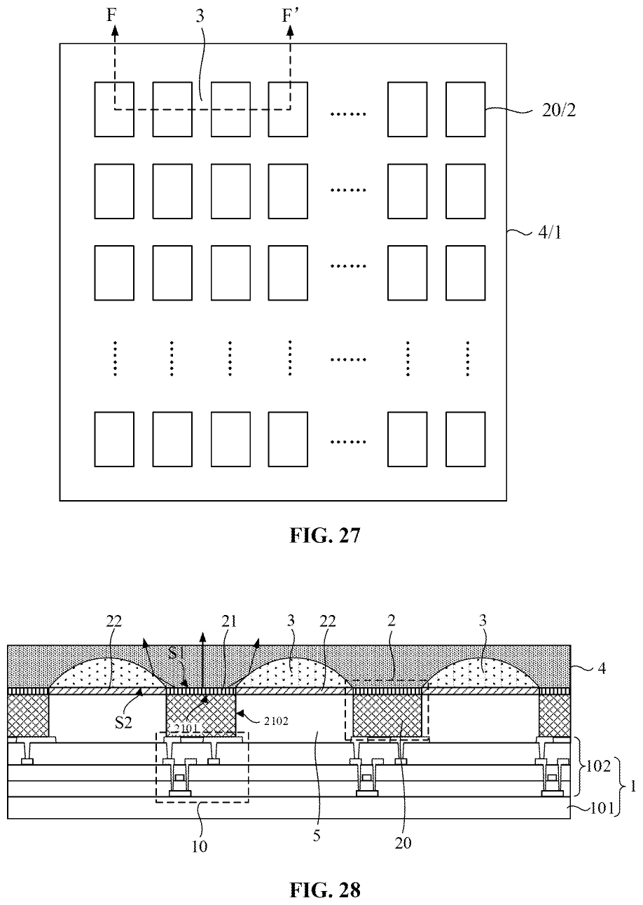

FIG. 27 is another diagram illustrating the structure of a display panel according to an embodiment of the present disclosure. FIG. 28 is a section view taken along FF′ of the display panel shown in FIG. 27.

Referring to FIGS. 27 and 28, in another embodiment of the present disclosure, the display panel includes a circuit substrate 1, multiple light-emitting components 2, and multiple microlenses 3. The multiple light-emitting components 2 are located on a side of the circuit substrate 1. A light-emitting component 2 includes a first surface S1 facing away from the circuit substrate 1. The light-emitting component 2 and/or the circuit substrate 1 includes a second surface S2. The second surface S2 at least partially surrounds the first surface S1. One of the first surface S1 or the second surface S2 is a hydrophilic surface. The other of the first surface S1 or the second surface S2 is a hydrophobic surface. The orthographic projection of a microlens 3 on the plane where the circuit substrate 1 is located does not overlap the orthographic projection of the first surface S1 on the plane where the circuit substrate 1 is located and overlaps the orthographic projection of the second surface on the plane where the circuit substrate 1 is located.

Different from the display panel of the preceding embodiments, in the display panel of this embodiment, the first surface S1 is located on the surface of the light-emitting component 2 facing away from the circuit substrate 1, and the microlens 3 has a repellency against the first surface S1 and has an affinity with the second surface S2, that is, the microlens 3 can be automatically aligned with the gap between light-emitting components 2. In the projection on the plane where the circuit substrate 1 is located, microlenses 3 surround the light-emitting component 2. Thus, when light is emitted from the surface of the microlens 3 facing away from the circuit substrate 1, angle-of-oblique-view light illuminates the surface of the microlens 3 and is reflected by the surface of the microlens 3 so that the angle-of-oblique-view light is approximately the same as front-angle-of-view light. Moreover, microlenses 3 around the light-emitting component 2 can adjust the angle of exit light of the light-emitting component 2 to make more light emitted at the angle of front view, thereby increasing the amount of the exit light at the angle of front view, reducing the power consumption of the light-emitting component 20, and improving the display effect. In the embodiments, the first surface S1 may be a hydrophobic surface, and the second surface S2 may be a hydrophilic surface. In this case, the microlens 3 may be made of a hydrophilic polymer. The microlens 3 made of a hydrophilic polymer has an affinity with the second surface S2 as a hydrophilic surface and has a repellency against the first surface S1 as a hydrophobic surface.

It is to be added that in the embodiments, the microlens 3 is essentially located in the gap between light-emitting components 2, so in the projection on the plane where the circuit substrate 1 is located, the shape of the microlens 3 depends on the shape of the second surface S2. When the second surface S2 is the surface of interconnected gaps between light-emitting components 2, the microlens 3 is essentially a mesh rather than multiple independent microlenses 3. When the second surface S2 is multiple independent surfaces at gaps between light-emitting components 2, the microlenses 3 are essentially multiple independent patterns.

Continuing to refer to FIG. 28, in the embodiments, the display panel also includes a planarization layer 4. The planarization layer 4 is located on the side of the microlens 3 facing away from the circuit substrate 1. The refractive index of the planarization layer 4 is greater than the refractive index of the microlens 3.

It is to be understood that reflection of light by the microlens 3 depends on the refractive index of the microlens 3 and the external refractive index as well as the shape of the microlens 3. As shown in FIG. 28, in the display panel of this embodiment, the planarization layer 4 is located on the side of the microlens 3 facing away from the circuit substrate 1. The planarization layer 4 covers and surrounds the microlens 3 so that angle-of-oblique-view light emitted from the surface of the light-emitting component 2 facing away from the circuit substrate 1 can be incident on the contact position between the microlens 3 and the planarization layer 4. The refractive index of the planarization layer 4 is greater than the refractive index of the microlens 3, so light incident on the contact position between the microlens 3 and the planarization layer 4 is in a light-tight to light-sparse propagation process so that more light is reflected on the contact position between the microlens 3 and the planarization layer 4, thereby implementing the focusing effect of the light.

Continuing to refer to FIG. 28, the light-emitting component 2 includes a light-emitting element 20 and a first modified film 21, where the surface of the light-emitting element 20 facing away from the circuit substrate 1 is a top surface 2101, the surface of the light-emitting element 20 adjacent to the top surface 2101 is a lateral surface 2102, and the first modified film 21 is at least partially located on the top surface 2101; and the display panel also includes a second modified film 22 that is at least partially located in the gap between light-emitting elements 20.

One of the first modified film 21 or the second modified film 22 is made of a hydrophilic material. The other of the first modified film 21 or the second modified film 22 is made of a hydrophobic material. The first surface S1 is the surface of the first modified film 21 facing away from the light-emitting element 20. The second surface S2 is the surface of the second modified film 22 facing away from the light-emitting element 20 and the circuit substrate 1.

Continuing to refer to FIG. 28, in one or more embodiments, the first modified film 21 is located on the top surface 2101, the orthographic projection of the first modified film 21 on the plane where the circuit substrate 1 is located coincides with the orthographic projection of the top surface 2101 on the plane where the circuit substrate 1 is located, and the orthographic projection of the second modified film on the plane where the circuit substrate 1 is located does not overlap the orthographic projection of the top surface 2101 on the plane where the circuit substrate 1 is located.

In one implementation of the present disclosure, the first modified film 21 completely covers the top surface 2101 of the light-emitting element 20, and the second modified film 22 is flush with the first modified film 21 and covers the gap between light-emitting elements 20. In view of factors such as light exit, the area of the first modified film 21 and the area of the second modified film 22 can also be reasonably designed, which is not limited herein. Illustratively, the second modified film 22 may also extend to the top surface 2101 of the light-emitting element 20. That is, the orthographic projection of the second modified film 22 on the plane where the circuit substrate 1 is located overlaps the orthographic projection of the top surface 2101 of the light-emitting element 20 on the plane where the circuit substrate 1 is located.

Moreover, the microlens 3 in the gap between light-emitting components 2 requires to reflect angle-of-oblique-view light of the light-emitting component 2, so the microlens 3 should be arranged at a height that is the same as the height of the light exit surface of the light-emitting component 2 in the direction perpendicular to the plane where the circuit substrate 1 is located. Based on this, the display panel shown in FIG. 28 also includes a fill layer 5. The fill layer 5 is located in the gap between light-emitting components 2. The second modified film 22 is located on the side of the fill layer 5 facing away from the circuit substrate 1. In this manner, when the microlens 3 is prepared, the material of the microlens 3 can be automatically aligned with the area where the second modified film 22 is located, that is, the gap between light-emitting components 2, thereby improving the pattern of the exit light of the light-emitting component 2.

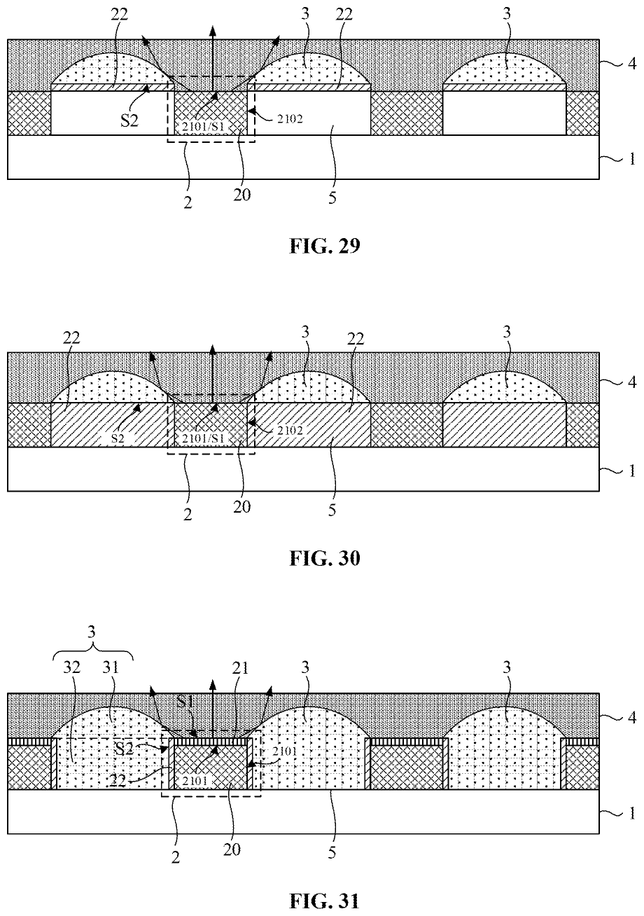

FIG. 29 is another section view of a display panel according to an embodiment of the present disclosure. Referring to FIG. 29, in some embodiments, the top surface 2101 of the light-emitting element 20 may be modified to ensure that the first surface S1 is formed on at least part of the top surface 2101 of the light-emitting element 20. The modification method is not limited herein and may be determined according to the actual requirements.

FIG. 30 is another section view of a display panel according to an embodiment of the present disclosure. Referring to FIG. 30, in some embodiments, the second modified film 22 may also serve as the fill layer 5 so that the fill layer 5 can lift the microlens 3 and enable the automatic alignment function of the microlens 3 for having a second surface S2 that has hydrophilicity or hydrophobicity, thereby merging and simplifying the process of making the fill layer 5 and the process of making the second modified film 22 and thus reducing production costs and time costs.

FIG. 31 is another section view of a display panel according to an embodiment of the present disclosure. Referring to FIG. 31, in some embodiments, the second modified film 22 is located on the lateral surface 2102 of the light-emitting component 2 and on the surface of the gap between light-emitting components 2 on the circuit substrate 1, and the microlens 3 partially fills the gap between light-emitting components 2.

When the microlens 3 is prepared, the material of the microlens 3 requires to fill only the gap between light-emitting components 2. The material of the microlens 3 repels the first surface S1 of the light-emitting component 2 facing away from the circuit substrate 1, so after completely filling the gap between light-emitting components 2, the remaining material of the microlens 3 form a convex surface, that is, the microlens 3, thereby enabling light reflection and refraction. The microlens 3 may include an upper portion 31 and a lower portion 32 that are integrally formed. The upper portion 31 is convex. The lower portion 32 fills the gap between light-emitting components 2. This solution makes the material of the microlens 3 automatically accommodated into the gap between light-emitting components 2 by using the affinity between the second modified film 22 and the material of the microlens 3 and the groove formed between light-emitting components 2; and makes the material of the microlens 3 form a convex structure during the filling process by using the repellency of the first modified film 21 on the top surface 2101 of the light-emitting element 20 of the light-emitting component 2 against the material of the microlens 3. In this manner, the preparation of the microlens 3 is completed, and the pattern of the exit light of the light-emitting component 2 is optimized.

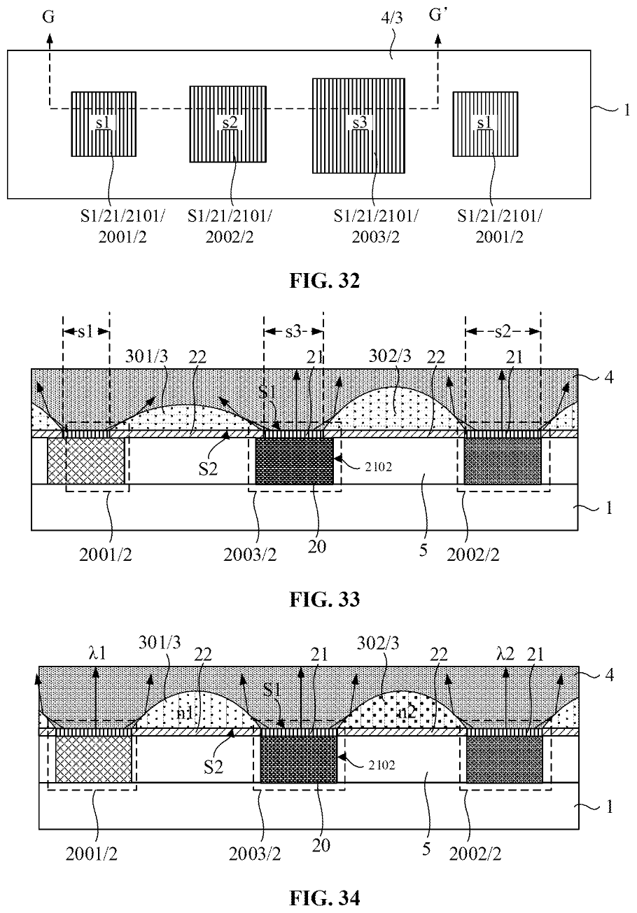

In the second display panel of the present disclosure, different solutions are provided for different light-emitting components. FIG. 32 is another diagram illustrating partial structure of a display panel according to an embodiment of the present disclosure. FIG. 33 is a section view taken along GG′ of the display panel shown in FIG. 32. Referring to FIGS. 32 and 33, in some embodiments, the light-emitting component 2 includes a first-color light-emitting component 2001 and a second-color light-emitting component 2002. The first-color light-emitting component 2001 and the second-color light-emitting component 2002 are light-emitting components of different colors. The area of the orthographic projection of the first modified film 21 of the first-color light-emitting component 2001 on the plane where the circuit substrate 1 is located is s1, and the area of the orthographic projection of the first modified film 21 of the second-color light-emitting component 2002 on the plane where the circuit substrate 1 is located is s2, where s1<s2.

Due to that s1<s2, light-emitting components of different colors are different in terms of the area of the orthographic projection of the first modified film 21 of the light-emitting component on the plane where the circuit substrate 1 is located, thereby ensuring that microlenses 3 formed on light-emitting components of different colors have different bottom areas to adapt to different light emission situations of light-emitting components of various colors, such as different luminous efficiencies and different angle-of-view brightnesses. In this manner, microlenses 3 in matching shapes are formed to overcome different light emission situations of light-emitting components of different colors so that light-emitting components of different colors have the same brightness, ensuring the display uniformity of the display panel and preventing color cast.

The first-color light-emitting component 2001 may be a green light-emitting component. The second-color light-emitting component 2002 may be a red light-emitting component or a blue light-emitting component. The following description uses an example in which the first-color light-emitting component 2001 is a green light-emitting component, and the second-color light-emitting component 2002 is a red light-emitting component. The luminous efficiency of existing green light-emitting elements is higher than that of existing red light-emitting elements. In view of the difference in luminous efficiency, to ensure that light-emitting components 2 of different colors have uniform brightness, in the embodiments, the area s2 of the orthographic projection of the first modified film 21 of the second-color light-emitting component 2002 (that is, red light-emitting component) on the plane where the circuit substrate 1 is located is set greater than the area s1 of the orthographic projection of the first modified film 21 of the first-color light-emitting component 2001 (that is, green light-emitting component), ensuring that the microlens (the microlens 302 in the example shown by the drawing) adjacent to the second-color light-emitting component 2002 (that is, red light-emitting component) has a smaller bottom area, a smaller radius of curvature, and a more convex shape. Thus, angle-of-oblique-view light of the second-color light-emitting component 2002 (that is, red light-emitting component) can be emitted at an angle close to the front angle of view after the light is reflected by the interface, increasing the amount of front-angle-of-view light, making up for the problem of low luminous efficiency of the red light-emitting component, overcoming the difference in brightness among light-emitting components of different colors caused by different luminous efficiencies, and thus preventing color cast.

The green light-emitting element has higher angle-of-view brightness than the red light-emitting element. Thus, the green light-emitting element has a larger projection area of the exit light, can emit more angle-of-oblique-view light, and can emit more divergent light. Therefore, in the embodiments, the first-color light-emitting component 2001 may be a red light-emitting component or a blue light-emitting component, and the second-color light-emitting component 2002 may be a green light-emitting component. Illustratively, the first-color light-emitting component 2001 may be a red light-emitting component, and the second-color light-emitting component 2002 may be a green light-emitting component. The area s2 of the orthographic projection of the first modified film 21 of the second-color light-emitting component 2002 (that is, green light-emitting component) on the plane where the circuit substrate 1 is located is set greater than the area s1 of the orthographic projection of the first modified film 21 of the first-color light-emitting component 2001 (that is, red light-emitting component), ensuring that the microlens (the microlens 302 in the example shown by the drawing) adjacent to the second-color light-emitting component 2002 (that is, green light-emitting component) has a smaller bottom area, a smaller radius of curvature, and a more convex shape. Thus, angle-of-oblique-view light of the second-color light-emitting component 2002 (that is, green light-emitting component) can be emitted at an angle close to the front angle of view after the light is reflected by the interface, increasing the amount of front-angle-of-view light, making up for the problem of high angle-of-view brightness of the red light-emitting component, overcoming the difference in brightness among light-emitting components of different colors caused by different luminous efficiencies, and thus preventing color cast.

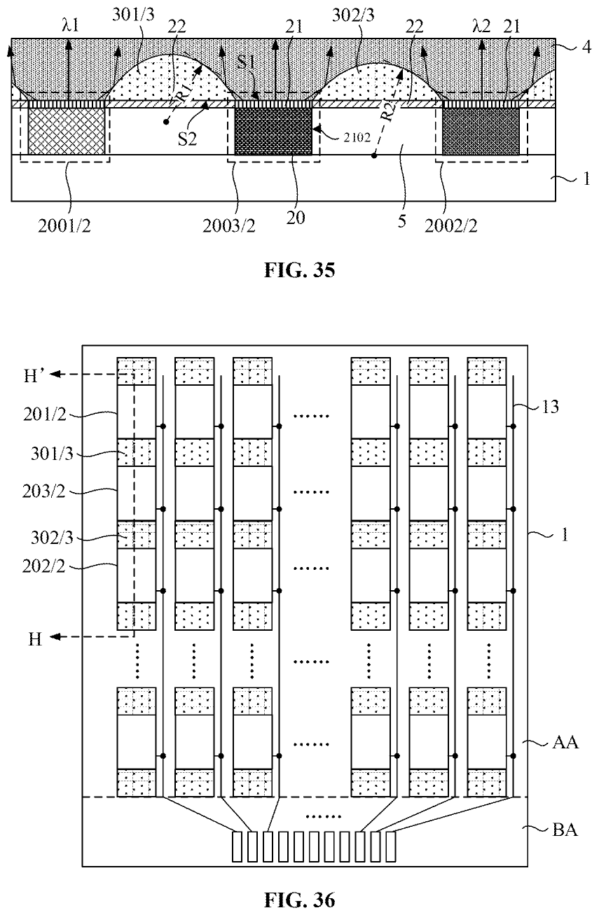

FIG. 34 is another section view of a display panel according to an embodiment of the present disclosure. FIG. 35 is another section view of a display panel according to an embodiment of the present disclosure. Referring to FIGS. 34 and 35, the light-emitting component 2 includes a first-color light-emitting component 2001 and a second-color light-emitting component 2002. The exit light center wavelength of the first-color light-emitting component 2001 is greater than the exit light center wavelength of the second-color light-emitting component 2002.

The microlenses 3 include a first microlens 301 and a second microlens 302. The first microlens 301 is disposed on the second surface S2 adjacent to the first-color light-emitting component 2001. The second microlens 302 is disposed on the second surface S2 adjacent to the second-color light-emitting component 2002.

The refractive index n1 of the first microlens 301 is less than the refractive index n2 of the second microlens 302, as shown in FIG. 34; or the radius R1 of curvature of the surface of the first microlens 301 facing away from the circuit substrate 1 is less than the radius R2 of curvature of the surface of the second microlens 302 facing away from the circuit substrate 1, as shown in FIG. 35.

The exit light center wavelength λ1 of the first-color light-emitting component 2001 is greater than the exit light center wavelength λ2 of the second-color light-emitting component 2002, so the first-color light-emitting component 2001 may be construed as a red light-emitting component, and the second-color light-emitting component 2002 may be construed as a green light-emitting component. As mentioned earlier, the light exit efficiency of the red light-emitting component is lower than that of the green light-emitting component. Thus, in the preceding two embodiments, the refractive index of the first microlens 301 corresponding to the first-color light-emitting component 2001 (that is, red light-emitting component) may be set relatively small, thereby increasing the refractive index difference between the first microlens 301 and the planarization layer 4 and thus causing light emitted by the first-color light-emitting component 2001 (that is, red light-emitting component) to be reflected more at the contact position between the planarization layer 4 and the first microlens 301; and the radius R1 of curvature of the convex surface of the first-color light-emitting component 2001 (that is, red light-emitting component) may be set relatively small, thereby making the shape of the first microlens 301 relatively more convex and causing light emitted by the first-color light-emitting component 2001 (that is, red light-emitting component) to be reflected more at the contact position between the planarization layer 4 and the first microlens 301. Therefore, angle-of-oblique-view light of the first-color light-emitting component 2001 (that is, red light-emitting component) can be emitted at an angle close to the front angle of view, increasing the amount of front-angle-of-view light and making up for the problem of lower brightness of the red light-emitting component than the green light-emitting component.

The red light-emitting element has higher angle-of-view brightness than the blue light-emitting element. Thus, the red light-emitting element has a larger projection area of the exit light, can emit more angle-of-oblique-view light, and can emit more divergent light. Therefore, in the embodiments, the first-color light-emitting component 2001 may be construed as a red light-emitting component, and the second-color light-emitting component 2002 may be construed as a blue light-emitting component. The exit light central wavelength λ1 of the red light-emitting component is in the range of 625-740 nm that is larger than the exit light central wavelength λ2 (in the range of 400-500 nm) of the blue light-emitting component. The refractive index of the first microlens 301 corresponding to the first-color light-emitting component 2001 (that is, red light-emitting component) may be set relatively small, thereby increasing the refractive index difference between the first microlens 301 and the planarization layer 4 and thus causing light emitted by the first-color light-emitting component 2001 (that is, red light-emitting component) to be reflected more at the contact position between the planarization layer 4 and the first microlens 301; and the radius of curvature of the convex surface of the first-color light-emitting component 2001 (that is, red light-emitting component) may be set relatively small, thereby making the shape of the first microlens 301 relatively more convex and causing light emitted by the first-color light-emitting component 2001 (that is, red light-emitting component) to be reflected more at the contact position between the planarization layer 4 and the first microlens 301. Therefore, angle-of-oblique-view light of the first-color light-emitting component 2001 (that is, red light-emitting component) can be emitted at an angle close to the front angle of view, increasing the amount of front-angle-of-view light and making up for the problem of higher angle-of-view brightness of the red light-emitting component than the blue light-emitting component.

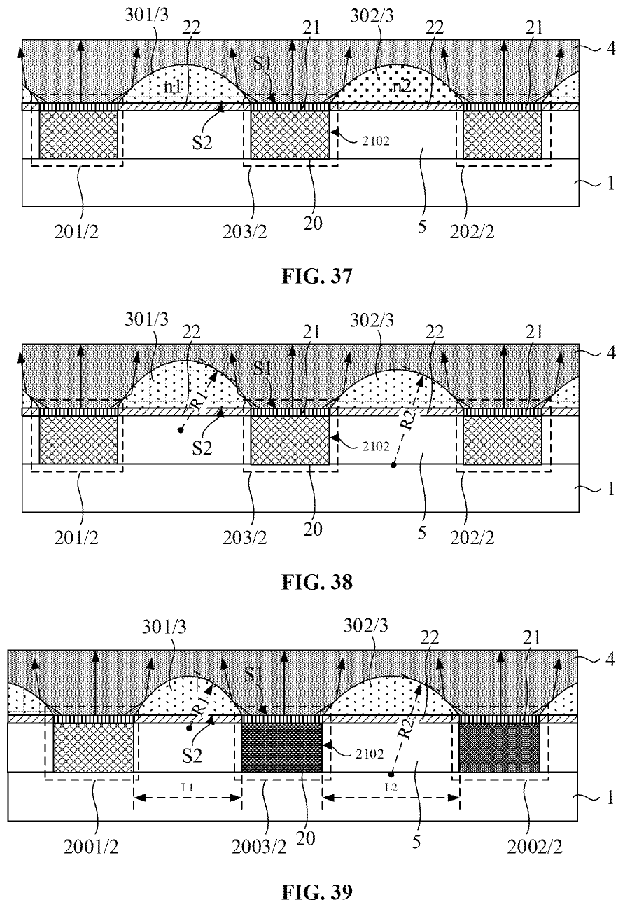

FIG. 36 is another diagram illustrating the structure of a display panel according to an embodiment of the present disclosure. FIG. 37 is a section view taken along HH′ of the display panel shown in FIG. 36. FIG. 38 is another section view taken along HH′ of the display panel shown in FIG. 36. Referring to FIGS. 36 to 38, the circuit substrate 1 includes a bonding region BA configured to bond a driver chip and/or a flexible wiring board.

The light-emitting component 2 includes a first light-emitting component 201 and a second light-emitting component 202. The distance between the first light-emitting component 201 and the bonding region BA is greater than the distance between the second light-emitting component 202 and the bonding region BA.

The microlenses 3 include a first microlens 301 and a second microlens 302. The first microlens 301 is disposed on the first surface S1 of the first light-emitting component 201. The second microlens 302 is disposed on the first surface S1 of the second light-emitting component 202.

The refractive index n1 of the first microlens 301 is less than the refractive index n2 of the second microlens 302, and/or the radius R1 of curvature of the surface of the first microlens 301 facing away from the circuit substrate 1 is less than the radius R2 of curvature of the surface of the second microlens 302 facing away from the circuit substrate 1.

In the embodiments, for the first light-emitting component 201 that is relatively far from the bonding region BA, the reflective effect of the corresponding first microlens 301 may be relatively increased, thereby relatively improving the brightness of the first light-emitting component 201 and making up for the negative impact of data signal attenuation on the brightness. In one or more embodiments, as shown in FIG. 37, the refractive index of the first microlens 301 corresponding to the first light-emitting component 201 relatively far from the bonding region BA is set relatively small, thereby increasing the refractive index difference between the first microlens 301 and the planarization layer 4 and thus causing light emitted by the first-color light-emitting component 2001 (that is, red light-emitting component) to be reflected more at the contact position between the planarization layer 4 and the first microlens 301. As shown in FIG. 38, the radius R1 of curvature of the convex surface of the first microlens 301 corresponding to the first light-emitting component 201 relatively far from the bonding region BA is set relatively small, thereby making the shape of the first microlens 301 relatively more convex and causing light emitted by the first-color light-emitting component 2001 (that is, red light-emitting component) to be reflected more at the contact position between the planarization layer 4 and the first microlens 301. Therefore, angle-of-oblique-view light of the first light-emitting component 201 whose brightness is relatively weak due to being relatively far from the bonding region BA can be emitted at an angle close to the front angle of view, increasing the amount of front-angle-of-view light and making up for the problem of low brightness caused by data signal attenuation.

In the display panel as described above, the microlenses may be construed as multiple independent microlenses that correspond to different light-emitting components and that are arranged adjacent. The second surface S2 in the second display panel may also be a surface that connects the gaps among the light-emitting components, that is, the projection of the second surface S2 on the plane where the circuit substrate 1 is located is a mesh; therefore, the microlenses may also be construed as an integral microlens whose projection is a mesh. Based on this, to achieve a brightness balance between different light-emitting components, embodiments of the present disclosure also provide corresponding implementations.

FIG. 39 is another section view of a display panel according to an embodiment of the present disclosure. Referring to FIG. 39, the display panel includes a first-color light-emitting component 2001 and a second-color light-emitting component 2002. The first-color light-emitting component 2001 and the second-color light-emitting component 2002 are light-emitting components of different colors. The distance L1 between the first-color light-emitting component 2001 and other light-emitting components and the distance L2 between the second-color light-emitting component 2002 and other light-emitting components satisfy that L1<L2.

The first-color light-emitting component 2001 may be construed as a red light-emitting component. The second-color light-emitting component 2002 may be construed as a green light-emitting component. The luminous efficiency of the red light-emitting component is lower than that of the green light-emitting component. To improve the brightness of the red light-emitting component, it is feasible to set the distance between the red light-emitting component and other light-emitting components to a smaller value, thereby controlling the surface, facing away from the circuit substrate 1, of the microlens (the first microlens 301) adjacent to the red light-emitting component to have a smaller radius R1 of curvature, making the shape of the microlens more convex, making reflected more angle-of-oblique-view light of the red light-emitting component, increasing the amount of front-angle-of-view light of the red light-emitting component, and making up for the problem of low brightness caused by a lower luminous efficiency of the red light-emitting component than the green light-emitting component.

The red light-emitting element has higher angle-of-view brightness than the blue light-emitting element. Thus, the red light-emitting element has a larger projection area of the exit light, can emit more angle-of-oblique-view light, and can emit more divergent light. Therefore, in the embodiments, the first-color light-emitting component 2001 may be construed as a red light-emitting component, the second-color light-emitting component 2002 may be construed as a blue light-emitting component, and the distance between the first-color light-emitting component 2001 (that is, red light-emitting component) and other light-emitting components may be set to a smaller value, thereby controlling the surface, facing away from the circuit substrate 1, of the microlens (the first microlens 301) adjacent to the first-color light-emitting component 2001 (that is, red light-emitting component) to have a smaller radius R1 of curvature, making the shape of the microlens more convex, making reflected more angle-of-oblique-view light of the red light-emitting component, increasing the amount of front-angle-of-view light of the red light-emitting component, and making up for the problem of low brightness caused by higher angle-of-view brightness of the red light-emitting component than the blue light-emitting component.

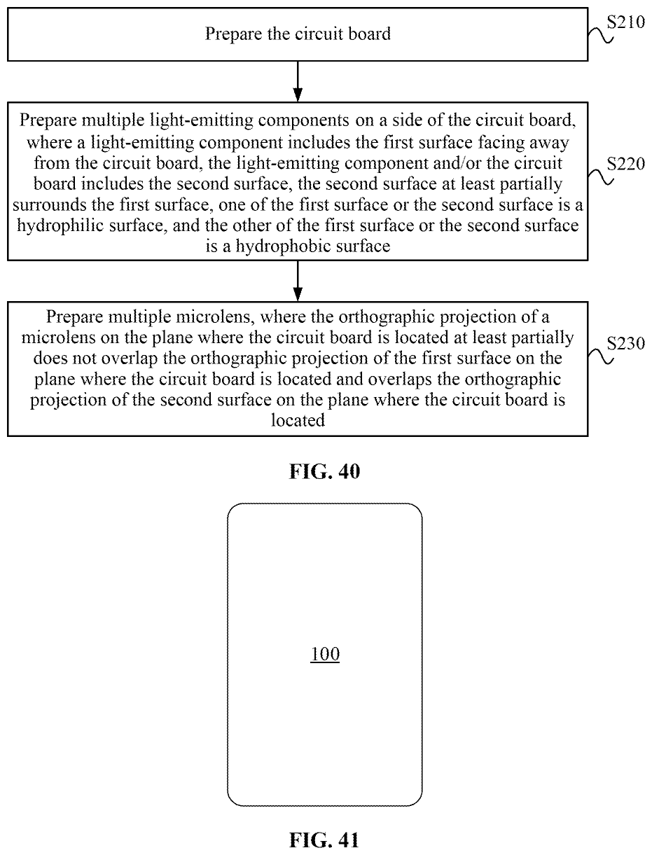

Embodiments of the present disclosure further provides a preparation method of the display panel as described above. FIG. 40 is a flowchart of another preparation method of a display panel according to an embodiment of the present disclosure. Referring to FIG. 40, the method is used for preparing the display panel of any previous embodiment. The method includes the following:

In S210, a circuit substrate is prepared.

In S220, multiple light-emitting components are prepared on a side of the circuit substrate, where a light-emitting component of the multiple light-emitting components includes a first surface facing away from the circuit substrate, the light-emitting component and/or the circuit substrate includes a second surface, the second surface at least partially surrounds the first surface, one of the first surface or the second surface is a hydrophilic surface, and the other of the first surface or the second surface is a hydrophobic surface.

In S230, multiple microlenses are prepared, where the orthographic projection of a microlens of the multiple microlenses on the plane where the circuit substrate is located at least partially does not overlap the orthographic projection of the first surface on the plane where the circuit substrate is located and overlaps the orthographic projection of the second surface on the plane where the circuit substrate is located.

The method includes preparing the circuit substrate; preparing multiple light-emitting components on a side of the circuit substrate, where the light-emitting component includes the first surface facing away from the circuit substrate, the light-emitting component and/or the circuit substrate includes the second surface, the second surface at least partially surrounds the first surface, one of the first surface or the second surface is a hydrophilic surface, and the other of the first surface or the second surface is a hydrophobic surface; and preparing a microlens, where the orthographic projection of the microlens on the plane where the circuit substrate is located at least partially does not overlap the orthographic projection of the first surface on the plane where the circuit substrate is located and overlaps the orthographic projection of the second surface on the plane where the circuit substrate is located. Thus, the first surface and the second surface that are different in hydrophilicity or hydrophobicity on the light-emitting elements and the circuit substrate enables position limitation and automatic alignment of the microlens when the microlens are prepared on the respective light-emitting elements, preventing the problem of nonuniform display caused by an excessive difference between the positions of the light-emitting elements relative to the respective microlenses due to insufficient external alignment precision.

Embodiments of the present disclosure provide a display device including the preceding display panel. FIG. 41 is a diagram illustrating the structure of a display device according to an embodiment of the present disclosure. Referring to FIG. 41, the display device includes the display panel 100 of any embodiment of the present disclosure. Therefore, the display device of this embodiment of the present disclosure has the beneficial effects of the display panel of any embodiment of the present disclosure. The beneficial effects are not described again herein. Illustratively, the display device may be an electronic device such as a mobile phone, a computer, a smart wearable device (for example, a smart watch), or an in-vehicle display device. This is not limited by the embodiments of the present disclosure.

What is claimed is:

1. A display panel, comprising:
a circuit substrate;
a plurality of light-emitting components located on a side of the circuit substrate, wherein at least one of the plurality of light-emitting components comprises a first surface facing away from the circuit substrate, at least one of the plurality of light-emitting components further comprises a second surface, the second surface at least partially surrounds the first surface, one of the first surface or the second surface is a hydrophilic surface, and an other of the first surface or the second surface is a hydrophobic surface; and
a plurality of microlenses, wherein the plurality of microlenses are located on a side of the plurality of light-emitting components facing away from the circuit substrate, and an orthographic projection of a microlens of the plurality of microlenses on a plane where the circuit substrate is located overlaps an orthographic projection of the first surface on the plane where the circuit substrate is located and does not overlap an orthographic projection of the second surface on the plane where the circuit substrate is located.

2. The display panel of claim 1, wherein
the orthographic projection of the microlens on the plane where the circuit substrate is located coincides with the orthographic projection of the first surface on the plane where the circuit substrate is located.

3. The display panel of claim 1, wherein
the first surface is a hydrophilic surface, and the second surface is a hydrophobic surface.

4. The display panel of claim 1, wherein
at least one of the plurality of light-emitting components comprises a light-emitting element, a first modified film, and a second modified film, wherein one of the first modified film or the second modified film is made of a hydrophilic material, and an other of the first modified film or the second modified film is made of a hydrophobic material; and
a surface of the light-emitting element facing away from the circuit substrate is a top surface, a surface of the light-emitting element adjacent to the top surface is a lateral surface, the first modified film is at least partially located on the top surface, and the second modified film is located on at least one of the top surface or the lateral surface; and
the first surface is a surface of the first modified film facing away from the light-emitting element, and the second surface is a surface of the second modified film facing away from the light-emitting element.

5. The display panel of claim 4, wherein
the first modified film is located on the top surface, and an orthographic projection of the first modified film on the plane where the circuit substrate is located coincides with an orthographic projection of the top surface on the plane where the circuit substrate is located.

6. The display panel of claim 5, wherein
the second modified film is located on the lateral surface, and an orthographic projection of the second modified film on the plane where the circuit substrate is located does not overlap the orthographic projection of the top surface on the plane where the circuit substrate is located.

7. The display panel of claim 6, wherein
a thickness of the second modified film in a direction perpendicular to the lateral surface is D2, and a thickness of the first modified film in a direction perpendicular to the top surface is D1, wherein D2>D1.

8. The display panel of claim 4, wherein
the second modified film is located on the top surface; and
an orthographic projection of the second modified film on the plane where the circuit substrate is located surrounds an orthographic projection of the first modified film on the plane where the circuit substrate is located.

9. The display panel of claim 8, wherein
in a direction perpendicular to the plane where the circuit substrate is located, a distance between a surface of the first modified film facing away from the circuit substrate and a surface of the circuit substrate is H1, and a distance between a surface of the second modified film facing away from the circuit substrate and the surface of the circuit substrate is H2, wherein
H2>H1.

10. The display panel of claim 4, wherein
a thickness of the first modified film in a direction perpendicular to the plane where the circuit substrate is located is less than 10 nm.

11. The display panel of claim 4, wherein
the plurality of light-emitting components comprises a first-color light-emitting component and a second-color light-emitting component, wherein the first-color light-emitting component and the second-color light-emitting component are light-emitting components of different colors; and
an area of an orthographic projection of the first modified film of the first-color light-emitting component on the plane where the circuit substrate is located is s1, and an area of an orthographic projection of the first modified film of the second-color light-emitting component on the plane where the circuit substrate is located is s2, wherein s1<s2.

12. The display panel of claim 11, wherein
in the first-color light-emitting component, the first modified film and the second modified film are both located on the top surface, and an orthographic projection of the second modified film on the plane where the circuit substrate is located surrounds the orthographic projection of the first modified film on the plane where the circuit substrate is located; and in the second-color light-emitting component, the first modified film is located on the top surface, the orthographic projection of the first modified film on the plane where the circuit substrate is located coincides with an orthographic projection of the top surface on the plane where the circuit substrate is located, and the second modified film is located on the lateral surface;
or
in the first-color light-emitting component and the second-color light-emitting component, the first modified film and the second modified film are both located on the top surface, and an orthographic projection of the second modified film on the plane where the circuit substrate is located surrounds the orthographic projection of the first modified film on the plane where the circuit substrate is located.

13. The display panel of claim 11, wherein
the first-color light-emitting component is a green light-emitting component, and the second-color light-emitting component is a red light-emitting component or a blue light-emitting component.

14. The display panel of claim 1, wherein
the plurality of light-emitting components comprises a first-color light-emitting component and a second-color light-emitting component, wherein an exit light center wavelength of the first-color light-emitting component is greater than an exit light center wavelength of the second-color light-emitting component; and
the plurality of microlens comprises a first microlens and a second microlens, wherein the first microlens is disposed on the first surface of the first-color light-emitting component, and the second microlens is disposed on the first surface of the second-color light-emitting component, and
wherein a refractive index of the first microlens is greater than a refractive index of the second microlens; or, a radius of curvature of a surface of the first microlens facing away from the circuit substrate is less than a radius of curvature of a surface of the second microlens facing away from the circuit substrate.

15. The display panel of claim 1, wherein
the circuit substrate includes a bonding region configured to bond at least one of a driver chip or a flexible wiring board;
the plurality of light-emitting components comprise a first light-emitting component and a second light-emitting component, and a distance between the first light-emitting component and the bonding region is greater than a distance between the second light-emitting component and the bonding region; and
the plurality of microlenses comprise a first microlens and a second microlens, wherein the first microlens is disposed on the first surface of the first light-emitting component, and the second microlens is disposed on the first surface of the second light-emitting component,
wherein one of the following is satisfied: a refractive index of the first microlens is greater than a refractive index of the second microlens, or, a radius of curvature of a surface of the first microlens facing away from the circuit substrate is less than a radius of curvature of a surface of the second microlens facing away from the circuit substrate.

16. The display panel of claim 1, further comprising
a planarization layer located on a side of the microlens facing away from the circuit substrate, wherein
a refractive index of the planarization layer is less than a refractive index of the microlens.

17. A display panel, comprising:
a circuit substrate;
a plurality of light-emitting components located on a side of the circuit substrate, wherein a light-emitting component of the plurality of light-emitting components comprises a first surface facing away from the circuit substrate, at least one of the light-emitting component or the circuit substrate comprises a second surface, the second surface at least partially surrounds the first surface, one of the first surface or the second surface is a hydrophilic surface, and an other of the first surface or the second surface is a hydrophobic surface; and
a plurality of microlenses, wherein an orthographic projection of a microlens of the plurality of microlenses on a plane where the circuit substrate is located does not overlap an orthographic projection of the first surface on the plane where the circuit substrate is located and overlaps an orthographic projection of the second surface on the plane where the circuit substrate is located.

18. The display panel of claim 17, further comprising
a planarization layer located on a side of the microlens facing away from the circuit substrate, wherein
a refractive index of the planarization layer is greater than a refractive index of the microlens.

19. A display device, comprising a display panel, wherein the display panel comprises:
a circuit substrate;
a plurality of light-emitting components located on a side of the circuit substrate, wherein at least one of the plurality of light-emitting components comprises a first surface facing away from the circuit substrate, at least one of the plurality of light-emitting components further comprises a second surface, the second surface at least partially surrounds the first surface, one of the first surface or the second surface is a hydrophilic surface, and an other of the first surface or the second surface is a hydrophobic surface; and
a plurality of microlenses, wherein the plurality of microlenses are located on a side of the plurality of light-emitting components facing away from the circuit substrate, and an orthographic projection of the microlens on a plane where the circuit substrate is located overlaps an orthographic projection of the first surface on the plane where the circuit substrate is located and does not overlap an orthographic projection of the second surface on the plane where the circuit substrate is located.

20. A preparation method of a display panel, applied to prepare the display panel of claim 1, comprising:
preparing the circuit substrate;
preparing the plurality of light-emitting components on a side of the circuit substrate, wherein at least one of the plurality of light-emitting components comprises the first surface facing away from the circuit substrate, and at least one of the plurality of light-emitting components further comprises the second surface, the second surface at least partially surrounds the first surface, one of the first surface or the second surface is a hydrophilic surface, and an other of the first surface or the second surface is a hydrophobic surface; and
preparing the plurality of microlenses, wherein the plurality of microlens are located on the side of the plurality of light-emitting components facing away from the circuit substrate, and an orthographic projection of the microlens on the plane where the circuit substrate is located overlaps an orthographic projection of the first surface on the plane where the circuit substrate is located and does not overlap an orthographic projection of the second surface on the plane where the circuit substrate is located.
